(19) United States
(12) Patent Application Publication
(10) Pub. No.: US 2026/0157159 A1
(43) Pub. Date: Jun. 4, 2026

(54) METHODS FOR FORMING FEEDTHROUGH VIAS IN A SEMICONDUCTING WAFER SUBSTRATE

(71) Applicant: Taiwan Semiconductor Manufacturing Company, LTD., Hsinchu (TW)

(72) Inventor: Tzu-Ging Lin, Kaohsiung (TW)

(21) Appl. No.: 18/963,936

(22) Filed: Nov. 29, 2024

(51) Int. Cl. H01L 21/768; H01L 23/48

(52) U.S. Cl. CPC H10W 20/023; H10W 20/20

(57) ABSTRACT

Methods for forming a longitudinal feedthrough via (FTV) on a substrate are described. A portion of a semiconducting fin in a jog region on a front side of the substrate is exposed. The exposed portion of the semiconducting fin is removed to create a first trench. The first trench is filled with at least one dielectric material to form a dielectric trench. The dielectric trench is then etched to an intermediate depth to form a second trench within the dielectric trench. The second trench is filled with an electrically conductive material. The dielectric trench is then etched from the back side of the substrate to form a backside volume that exposes the electrically conductive material in the second trench. The backside volume is filled with additional electrically conductive material to form the longitudinal FTV. The longitudinal FTV is perpendicular to a cut metal gate trench.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A and FIG. 1B together form a flow chart illustrating a method for forming a CPODE feedthrough via between the front side and the back side of a semiconducting device, in accordance with some embodiments.

FIGS. 2A-2E are different views of a partially-completed substrate prior to starting the method of FIG. 1. FIG. 2A is a plan view. FIG. 2B is a first X-axis view of the substrate along line X1-X1 of FIG. 2A. FIG. 2C is a second X-axis view of the substrate along line X2-X2 of FIG. 2A. FIG. 2D is a first Y-axis view of the substrate along line Y1-Y1 of FIG. 2A. FIG. 2E is a second Y-axis view of the substrate along line Y2-Y2 of FIG. 2A.

FIGS. 3A-3D are different views of the substrate after a hard mask layer and patterning layers are applied. FIG. 3A is a first X-axis view of the substrate along line X1-X1 of FIG. 2A. FIG. 3B is a second X-axis view of the substrate along line X2-X2 of FIG. 2A. FIG. 3C is a first Y-axis view of the substrate along line Y1-Y1 of FIG. 2A. FIG. 3D is a second Y-axis view of the substrate along line Y2-Y2 of FIG. 2A.

FIGS. 4A-4D are different views of the substrate after patterning the hard mask layer. FIG. 4A is a first X-axis view of the substrate along line X1-X1 of FIG. 2A. FIG. 4B is a second X-axis view of the substrate along line X2-X2 of FIG. 2A. FIG. 4C is a first Y-axis view of the substrate along line Y1-Y1 of FIG. 2A. FIG. 4D is a second Y-axis view of the substrate along line Y2-Y2 of FIG. 2A.

FIGS. 5A-5D are different views of the substrate after forming a trench in an exposed area. FIG. 5A is a first X-axis view of the substrate along line X1-X1 of FIG. 2A. FIG. 5B is a second X-axis view of the substrate along line X2-X2 of FIG. 2A. FIG. 5C is a first Y-axis view of the substrate along line Y1-Y1 of FIG. 2A. FIG. 5D is a second Y-axis view of the substrate along line Y2-Y2 of FIG. 2A.

FIGS. 6A-6D are different views of the substrate after the trench is filled with a dielectric material to form a dielectric trench. FIG. 6A is a first X-axis view of the substrate along line X1-X1 of FIG. 2A. FIG. 6B is a second X-axis view of the substrate along line X2-X2 of FIG. 2A. FIG. 6C is a first Y-axis view of the substrate along line Y1-Y1 of FIG. 2A. FIG. 6D is a second Y-axis view of the substrate along line Y2-Y2 of FIG. 2A.

FIGS. 7A-7D are different views of the substrate after planarization of the front side of the substrate. FIG. 7A is a first X-axis view of the substrate along line X1-X1 of FIG. 2A. FIG. 7B is a second X-axis view of the substrate along line X2-X2 of FIG. 2A. FIG. 7C is a first Y-axis view of the substrate along line Y1-Y1 of FIG. 2A. FIG. 7D is a second Y-axis view of the substrate along line Y2-Y2 of FIG. 2A.

FIGS. 8A-8D are different views of the substrate after a second trench is formed within the dielectric trench. FIG. 8A is a first X-axis view of the substrate along line X1-X1 of FIG. 2A. FIG. 8B is a second X-axis view of the substrate along line X2-X2 of FIG. 2A. FIG. 8C is a first Y-axis view of the substrate along line Y1-Y1 of FIG. 2A. FIG. 8D is a second Y-axis view of the substrate along line Y2-Y2 of FIG. 2A.

FIGS. 9A-9E are different views of the substrate after the second trench is filled with an electrically conductive material. FIG. 9A is a plan view, with lines X1-X1, X2-X2, Y1-Y1, and Y2-Y2 drawn again as in FIG. 2A. FIG. 9B is a first X-axis view of the substrate along line X1-X1. FIG. 9C is a second X-axis view of the substrate along line X2-X2. FIG. 9D is a first Y-axis view of the substrate along line Y1-Y1. FIG. 9E is a second Y-axis view of the substrate along line Y2-Y2.

FIGS. 10A-10D are different views of the substrate after routing is formed on the front side of the substrate. FIG. 10A is a first X-axis view of the substrate along line X1-X1 of FIG. 9A. FIG. 10B is a second X-axis view of the substrate along line X2-X2 of FIG. 9A. FIG. 10C is a first Y-axis view of the substrate along line Y1-Y1 of FIG. 9A. FIG. 10D is a second Y-axis view of the substrate along line Y2-Y2 of FIG. 9A.

FIGS. 11A-11D are different views of the substrate after the substrate has been flipped. FIG. 11A is a first X-axis view of the substrate along line X1-X1 of FIG. 9A. FIG. 11B is a second X-axis view of the substrate along line X2-X2 of FIG. 9A. FIG. 11C is a first Y-axis view of the substrate along line Y1-Y1 of FIG. 9A. FIG. 11D is a second Y-axis view of the substrate along line Y2-Y2 of FIG. 9A.

FIGS. 12A-12D are different views of the substrate after the back side of the substrate has been planarized to expose cut metal gate (CMG) trenches). FIG. 12A is a first X-axis view of the substrate along line X1-X1 of FIG. 9A. FIG. 12B is a second X-axis view of the substrate along line X2-X2 of FIG. 9A. FIG. 12C is a first Y-axis view of the substrate along line Y1-Y1 of FIG. 9A. FIG. 12D is a second Y-axis view of the substrate along line Y2-Y2 of FIG. 9A.

FIGS. 13A-13D are different views of the substrate after a hard mask layer has been patterned and etched. FIG. 13A is a first X-axis view of the substrate along line X1-X1 of FIG. 9A. FIG. 13B is a second X-axis view of the substrate along line X2-X2 of FIG. 9A. FIG. 13C is a first Y-axis view of the substrate along line Y1-Y1 of FIG. 9A. FIG. 13D is a second Y-axis view of the substrate along line Y2-Y2 of FIG. 9A.

FIGS. 14A-14D are different views of the substrate after the dielectric trench has been etched to form a backside volume and expose the second trench. FIG. 14A is a first X-axis view of the substrate along line X1-X1 of FIG. 9A. FIG. 14B is a second X-axis view of the substrate along line X2-X2 of FIG. 9A. FIG. 14C is a first Y-axis view of the substrate along line Y1-Y1 of FIG. 9A. FIG. 14D is a second Y-axis view of the substrate along line Y2-Y2 of FIG. 9A.

FIGS. 15A-15D are different views of the substrate after the backside volume dielectric trench has been filled with an electrically conductive material to complete the formation of the CPODE feedthrough via (FTV). FIG. 15A is a first X-axis view of the substrate along line X1-X1 of FIG. 9A. FIG. 15B is a second X-axis view of the substrate along line X2-X2 of FIG. 9A. FIG. 15C is a first Y-axis view of the substrate along line Y1-Y1 of FIG. 9A. FIG. 15D is a second Y-axis view of the substrate along line Y2-Y2 of FIG. 9A.

FIGS. 16A-16D are different views of the substrate after the back side of the substrate has been planarized to remove excess material. FIG. 16A is a first X-axis view of the substrate along line X1-X1 of FIG. 9A. FIG. 16B is a second X-axis view of the substrate along line X2-X2 of FIG. 9A. FIG. 16C is a first Y-axis view of the substrate along line Y1-Y1 of FIG. 9A. FIG. 16D is a second Y-axis view of the substrate along line Y2-Y2 of FIG. 9A.

FIGS. 17A-17D are different views of the substrate after routing is formed on the back side of the substrate. FIG. 17A is a first X-axis view of the substrate along line X1-X1 of FIG. 9A. FIG. 17B is a second X-axis view of the substrate along line X2-X2 of FIG. 9A. FIG. 17C is a first Y-axis view of the substrate along line Y1-Y1 of FIG. 9A. FIG. 17D is a second Y-axis view of the substrate along line Y2-Y2 of FIG. 9A.

FIG. 18A is an X-axis view of a first example embodiment of the semiconducting device, showing the substrate along line X1-X1 of FIG. 9A. In this embodiment, the source/drain region can be contacted from either side of the substrate.

FIG. 18B is an X-axis view of a second example embodiment of the semiconducting device, showing the substrate along line X2-X2 of FIG. 9A. In this embodiment, an additional FTV is formed through a source/drain region.

FIG. 18C is a Y-axis view of a third example embodiment of the semiconducting device, showing the substrate along line Y1-Y1 of FIG. 9A. In this embodiment, multiple FTVs are formed through the dielectric trench in the jog region.

FIG. 18D is a plan view, and FIG. 18E is a Y-axis view of a fourth example embodiment of the semiconducting device, showing the substrate along line X2-X2 of FIG. 18D. Here, the CPODE FTV is much larger, and replaces a semiconducting fin portion.

FIGS. 19A-19E are different views of a fourth example embodiment of the semiconducting device, showing how the dimensions of the CPODE FTV can be changed. FIG. 19A is a plan view of the partially-completed substrate as in FIG. 2A, with lines X1-X1 and Y1-Y1 as indicated. FIG. 19B is a first X-axis view of the partially-completed substrate along line X1-X1. FIG. 19C is a second X-axis view along line X1-X1 after formation of the CPODE FTV. FIG. 19D is a first Y-axis view of the partially-completed substrate along line Y1-Y1. FIG. 19E is a second Y-axis view of the substrate along line Y1-Y1 after formation of the CPODE FTV.

FIGS. 20A-20F are different views of a fifth example embodiment of the semiconducting device, showing formation of a feedthrough via through a cut metal gate trench (i.e. a CMG FTV). FIG. 20A is a plan view of the partially-completed substrate as in FIG. 2A, with lines X1-X1 and Y1-Y1 as indicated. FIG. 20B is a first X-axis view of the partially-completed substrate along line X1-X1. FIG. 20C is a second X-axis view along line X1-X1 after formation of the CMG FTV.

FIG. 20D is a first Y-axis view of the partially-completed substrate along line Y1-Y1. FIG. 20E is a second Y-axis view of the substrate along line Y1-Y1 after formation of a CMG volume within the CMG trench. FIG. 20F is a third Y-axis view of the substrate along line Y1-Y1 after formation of the CMG FTV. The CMG FTV extends in the longitudinal direction (i.e. along the X-axis).

FIG. 20G is a plan view of another embodiment, where multiple CMG FTVs are formed in a CMG trench. In this example, three CMG FTVs are present in the CMG trench. Again, any number of FTVs may be present depending on the dimensions of the CMG trench and the desired application, including zero, one, two, three, or more.

FIGS. 21A-21C illustrate three different combinations of different semiconducting fins/fin portions joined together in a jog region. Three different combinations are illustrated here. In FIG. 21A, two fins having different widths are joined together in the jog region. In FIG. 21B, one side of a fin is joined to multiple fins in the jog region. In FIG. 21C, two fins having the same width are offset from each other at the jog region.

FIGS. 21D-21I illustrate six different combinations of jog patterns that contain multiple jog regions. FIGS. 21D-21F show three different symmetric jog patterns. FIGS. 21G-21I show three different asymmetric jog patterns

FIG. 22A is a plan view illustration of the front side of a wafer, illustrating a CMG FTV and a CPODE FTV used for routing to metal contacts for source or drain electrodes on the front side.

FIG. 22B is a plan view illustration of the back side of a wafer, illustrating a CMG FTV and a CPODE FTV used for routing to metal contacts for source electrodes on the back side.

FIG. 23A is a plan view of a first embodiment of a jog pattern that can be used as a feedthrough cell (FTC).

FIG. 23B is a plan view of a second embodiment of a jog pattern that can be used as a feedthrough cell (FTC).

FIG. 24A is a plan view of a first embodiment showing a jog pattern that can be used as a feedthrough cell (FTC) and connected CPODE structures to disable surrounding transistors along one axis.

FIG. 24B is a plan view of a second embodiment showing a jog pattern that can be used as a feedthrough cell (FTC) and connected CPODE structures to disable surrounding transistors along one axis.

FIG. 25A is a plan view of a first embodiment showing a jog pattern that can be used as a feedthrough cell (FTC) and disconnected CPODE structures to disable surrounding transistors along one axis.

FIG. 25B is a plan view of a second embodiment showing a jog pattern that can be used as a feedthrough cell (FTC) and disconnected CPODE structures to disable surrounding transistors along one axis.

FIG. 26 is a plan view of a first embodiment showing a jog pattern that can be used as a feedthrough cell (FTC) and disconnected CPODE structures to disable surrounding transistors along two axes.

FIG. 27A is a plan view of a first embodiment showing a jog pattern that can be used as a feedthrough cell (FTC), connected CPODE structures to disable surrounding transistors along one axis, and cut metal gate (CMG) trenches.

FIG. 27B is a plan view of a second embodiment showing a jog pattern that can be used as a feedthrough cell (FTC), connected CPODE structures to disable surrounding transistors along one axis, and cut metal gate (CMG) trenches.

FIG. 28 is a plan view of an embodiment showing a jog pattern that can be used as a feedthrough cell (FTC), CPODE structures to disable surrounding transistors along two axes, and cut metal gate (CMG) trenches.

FIG. 29A is a plan view of a first embodiment showing a jog pattern that can be used as a feedthrough cell (FTC) which does not have source/drain regions formed about its perimeter.

FIG. 29B is a plan view of a second embodiment showing a jog pattern that can be used as a feedthrough cell (FTC) which does not have source/drain regions formed about its perimeter.

FIG. 30A is a plan view of a first embodiment showing a jog pattern that can be used as a feedthrough cell (FTC) which does not have source/drain regions or semiconducting channels formed about its perimeter.

FIG. 30B is a plan view of a second embodiment showing a jog pattern that can be used as a feedthrough cell (FTC) which does not have source/drain regions or semiconducting channels formed about its perimeter.

FIGS. 31A-31G together illustrate a general method for reducing layout-dependent effects and reducing parasitic capacitance in the transistors/integrated circuits of the present disclosure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

The terms “feedthrough via”, “FTV”, “feedthrough cell”, “FTC”, “through silicon via”, and “TSV” may be used interchangeably to relate to a structure that passes through a wafer substrate from its front side to its back side.

It is noted that as used herein, the term “trench” is used to refer to a volume which may be empty or may be filled, and which should be clear from the context of the discussion.

The present disclosure relates to methods and devices for forming communications channels between the front side and the back side of a wafer substrate or semiconducting device, especially with respect to Gate-All-Around (GAA) transistors. GAA transistors may use nanosheets as the semiconducting channel, and the number of nanosheets and their width can also be varied to obtain desired performance characteristics.

Jog designs, where structures in a given layer have a non-linear shape, can substantially raise the efficiency of area usage. In the present disclosure, a continuous poly on diffusion edge (CPODE) feedthrough via (FTV) or feedthrough cell (FTC) is formed within or adjacent the jog region to form communications channel(s) between the front side and the back side of the wafer substrate. The CPODE FTV is formed by etching away one or more semiconducting fins, forming a trench in the substrate, filling the trench with a dielectric material, forming a second trench within the dielectric trench, and filling the second trench with an electrically conductive material. This creates one or more vias with low parasitic capacitance between the front side and the back side of the wafer substrate in an area-efficient manner.

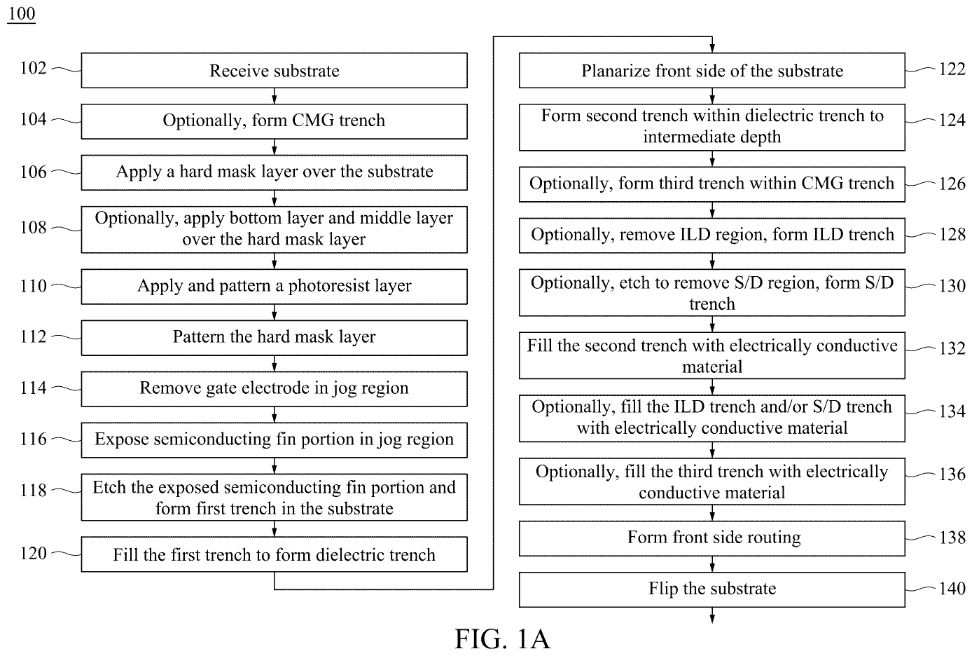

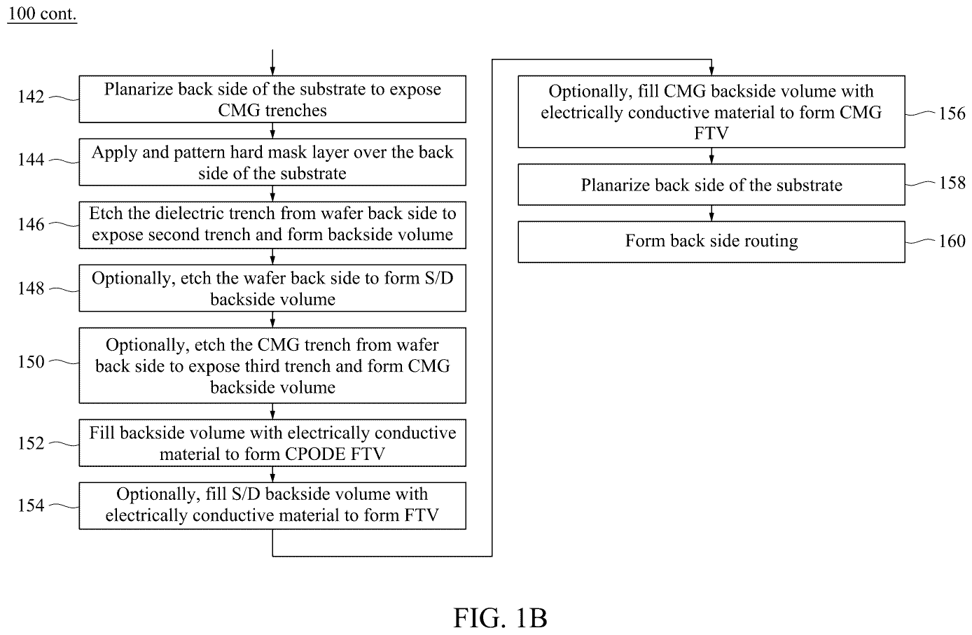

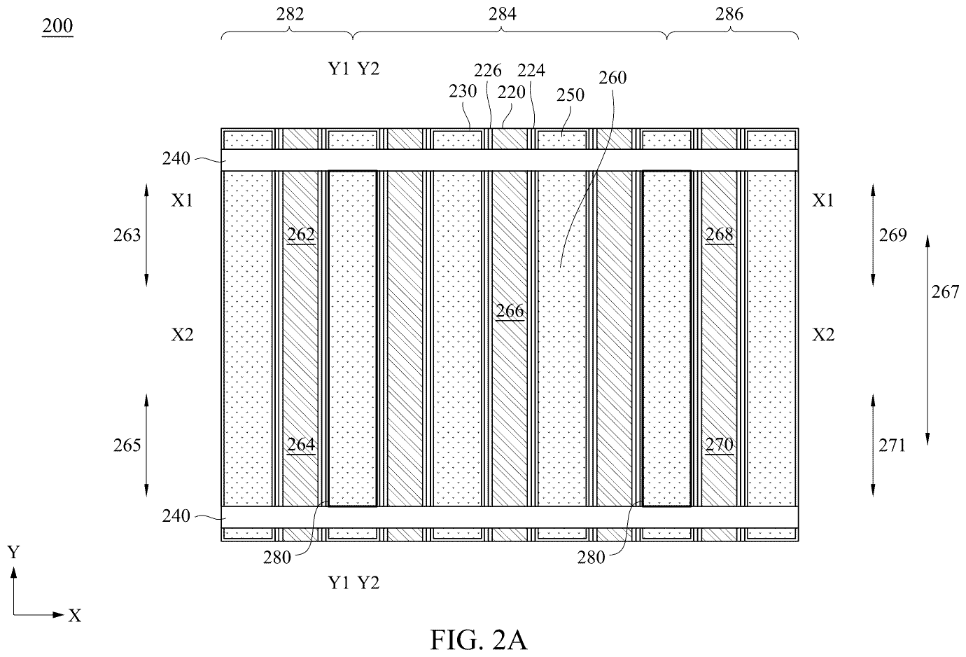

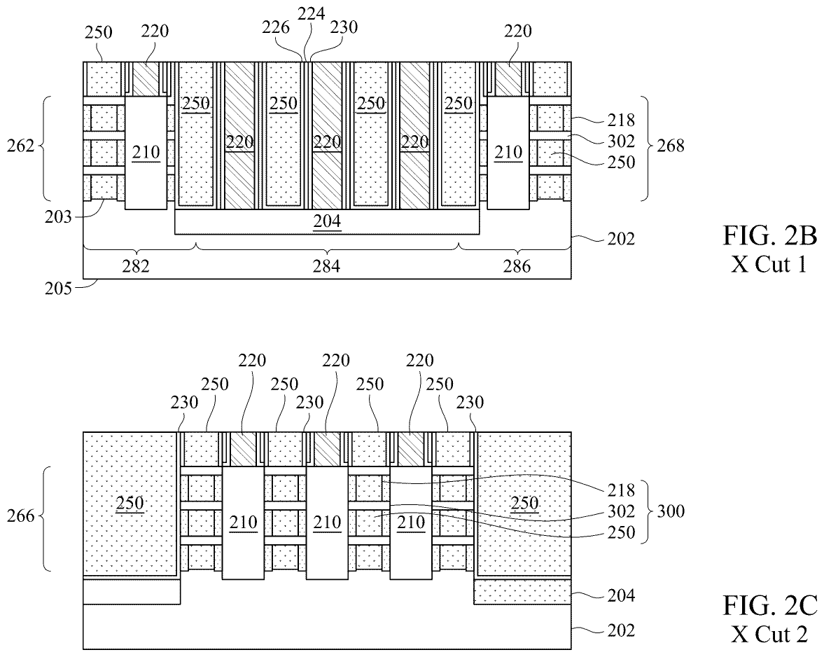

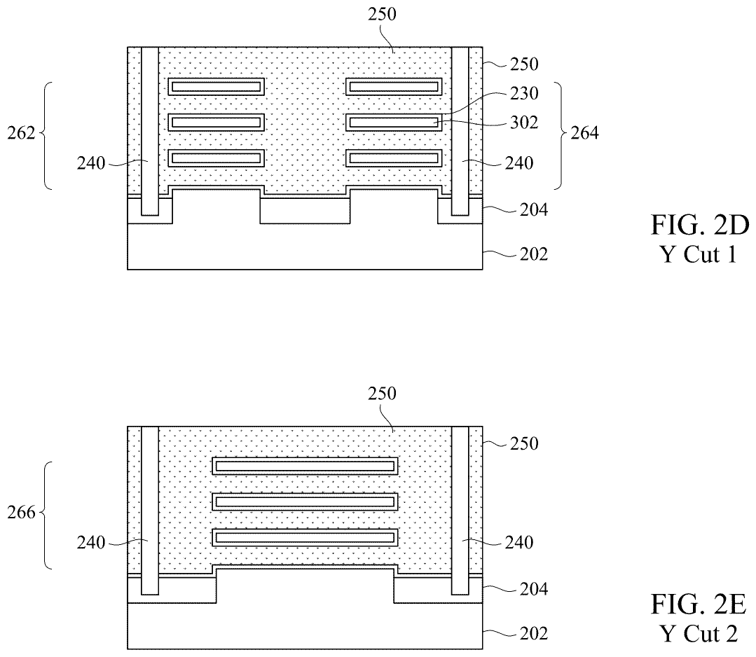

FIG. 1A and FIG. 1B together form a flow chart illustrating a method 100 for forming a CPODE feedthrough via (FTV) on a substrate, in accordance with some embodiments. FIGS. 2A-17D illustrate various steps of the method. These figures provide different views for better understanding. While the method steps are discussed below in terms of forming one jog region and are illustrated as forming two jog regions, such discussion should also be broadly construed as applying to the concurrent formation of multiple CPODE FTVs upon the substrate. It is noted that not all steps described in the flow chart are required, and not all method steps are described in the flow chart.

Initially, FIGS. 2A-2E show a beginning state of a partially completed transistor or integrated circuit 200 on the wafer substrate 202 as received in step 102 of FIG. 1A, before the method steps are performed. Referring first to the plan view of FIG. 2A, a set of gate electrodes 250 is shown. Located between each pair of gate electrodes 250 are a pair of gate dielectric layers 230, a pair of dielectric spacers 224, a pair of continuous etch stop layers (CESL) 226, and an interlayer dielectric (ILD) layer 220.

The dotted lines indicate the location of semiconducting fins below the gate electrodes 250 and the other layers 230, 224, 226, 220. As illustrated in this example, a first fin portion 262 and a second fin portion 264 are located in a first region 282 of the substrate. A third fin portion 266 is located in a second or middle region 284 of the substrate. Finally, a fourth fin portion 268 and a fifth fin portion 270 are located in a third region 286 of the substrate.

As illustrated here, the first region 282 is adjacent the second region 284. Similarly, the second region 284 is adjacent the third region 286, and separates the first region from the third region. However, it is noted that these terms are merely identifying labels for these regions. Thus, any one of the three regions 282, 284, 286 could be designated a first region, a second region, etc. The jog regions 280 are located between two regions 282, 284 and 284, 286. Put another way, each jog region includes part of two regions, or overlaps two regions.

The first fin portion 262 has a width 263. The second fin portion 264 has a width 265. The third fin portion 266 has a width 267. The fourth fin portion 268 has a width 269. The fifth fin portion 270 has a width 271. The width of each fin portion is independent from that of the other fin portions. As illustrated here, the width 267 of the third fin portion is greater than the width 263, 265, 269, 271 of the other fin portions.

Prior to forming the CPODE feedthrough via, the five fin portions are joined together, and can be considered as forming a single semiconducting fin 260 that extends in the longitudinal direction (i.e. along the X-axis). As another alternative, each fin portion can be considered a semiconducting fin by itself. As a second alternative, the fin portions in each region can be considered together as a semiconducting fin for that region, because the current density in the region is proportional to the sum of the widths of the fin portions in the region. The locations where the fin portions join each other can be referred to as a jog region 280, and two such jog regions are indicated here with a rectangular shape. It is noted that for purposes of simplicity, the jog region is shown as having a 90° intersection between the fin portions, but their joinder angle can be lower. For example, then, a single semiconducting fin could be described as changing width at the jog region.

Referring now to FIG. 2B, a cross-sectional view is provided. The integrated circuit is built upon a substrate 202, which has a front side 203 and a back side 205. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Continuing, a shallow trench isolation (STI) region or layer 204 is present upon the front side of the substrate 202 around the fin portions. The dielectric material in the STI layer is commonly silicon dioxide, although other dielectric materials can also be used such as undoped polysilicon, silicon oxide (e.g. SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. The STI layer is usually deposited prior to building the various layers of the semiconducting fin 260/fin portions 262, 264, 266, 268, 270 on the front side of the substrate. If desired, the dielectric material can be deposited to a level above that of the substrate, then recessed back down to the desired height.

In FIG. 2B, the first fin portion 262 and the fourth fin portion 268 are visible in the X-axis view along line X1-X1. In FIG. 2C, the third fin portion 266 is visible in the X-axis view along line X2-X2. In FIG. 2D, the first fin portion 262 and the second fin portion 264 are visible in the Y-axis view along line Y1-Y1. In FIG. 2E, the third fin portion 266 is visible in the Y-axis view along line Y2-Y2.

As most easily seen in FIG. 2C, each fin portion contains a stack 300 formed by alternating layers of a semiconducting nanosheet 302 and a sacrificial layer (no longer present). These layers can be made using CVD, atomic layer deposition (ALD), molecular beam epitaxy (MBE), liquid phase epitaxy (LPE), liquid phase epitaxy (VPE), or any other appropriate process. Each semiconducting nanosheet layer may be, for example, silicon or other materials suitable for the substrate. The sacrificial layers can be made of any suitable material which can be selectively etched in comparison to the other materials that will be used in the transistor, such as for example SiGe.

Also present are source/drain regions 210 located within the fin portions. In particular embodiments, these regions are formed from epitaxial silicon using CVD, MOCVD, MBE, LPE, VPE, UHVCVD, or the like. They may also be doped with appropriate dopants such as boron, gallium, or indium; or phosphorus or arsenic. Inner dielectric spacers 218 separate the semiconducting nanosheets 302 from each other.

Continuing, interlayer dielectric (ILD) regions 220 and gate electrodes 250 are placed in alternating fashion over the substrate. As can be seen in FIG. 2B and FIG. 2C, the ILD regions 220 are aligned with and placed over the source/drain regions 210.

The ILD regions electrically separate the source/drain regions from the gate electrodes. The ILD regions may be formed from any dielectric material, and do not need to be a high-k dielectric material. The ILD can be deposited using any appropriate method, for example CVD. The ILD regions 220 are surrounded on two sides by the CESL 226, and then by the low-k dielectric spacers 224. The CESL is made from a different material than the ILD regions 220 and the low-k dielectric spacers 224, and is commonly silicon nitride. The low-k dielectric layer 224 has a dielectric constant equal to or less than that of silicon nitride (˜7). Suitable materials may include various nitrides or oxides.

Located between the ILD regions are gate electrodes 250. A gate dielectric layer 230 is present on three sides of each gate electrode. The CPODE FTVs are typically formed where a gate electrode is located.

Finally, two cut metal gate (CMG) trenches 240 are illustrated on either side of the semiconducting fin 260. As illustrated in FIG. 2A, the two CMG trenches 240 run along the X-axis (i.e. longitudinal direction), and the gate electrodes 250 run along the Y-axis (i.e. latitudinal direction). The jog region 280 is located between the CMG trenches 240. As illustrated in FIG. 2D and FIG. 2E, the CMG trenches 240 extend into the STI layer 204, and thus electrically isolate the gate electrodes 250 between them.

The partially completed integrated circuit 200 on the wafer substrate 202 may be prepared by first etching the substrate to define trenches for the STI layer 204. The trenches are then filled with a dielectric material to form the STI layer. Next, the fin stack 300 is formed by depositing the alternating layers of semiconducting nanosheets 302 and sacrificial layers upon the substrate. A hard mask is applied and the fin stack is etched to obtain the semiconducting fin with fin portions in their desired location. An anisotropic etch of the sacrificial layers is performed, and inner dielectric spacers 218 are formed in these etched locations on the exposed exterior walls of the fin stack. The fin stack is then etched to create trenches in desired locations for the source/drain regions 210. Another anisotropic etch is performed on the newly exposed surfaces of the sacrificial layers within these trenches, and inner dielectric spacers 218 are again formed in the newly-etched locations. A dummy oxide layer is then formed on exposed silicon surfaces. Epitaxial silicon is then deposited into the trenches to form the source/drain regions 210. A dummy gate material, such as polysilicon is then deposited over the substrate. Another photomask is applied and the dummy gate material is etched to create trenches over the source/drain regions and to form dummy gate regions. A low-k dielectric spacer 224 is then applied to the exposed vertical surfaces of the dummy gate regions. The ILD regions 220 are then formed over the source/drain regions. The CESL 224 is then applied over the three exposed sides of the ILD regions. The dummy gate regions are then removed to expose the sacrificial layers, which are etched away. A gate dielectric layer is applied to the exposed surfaces, which include the semiconducting nanosheets. The dummy gate regions are then filled to form gate electrodes 250. The CMG trenches 240 are then formed across the gate electrodes 250. The partially-completed substrate of FIGS. 2A-2E is thus obtained. If the partially-completed substrate does not contain CMG trenches, then in step 104 of FIG. 1A, CMG trenches are formed in the substrate by etching the substrate to form empty trenches, then filling the empty trenches with a dielectric material to obtain the CMG trenches.

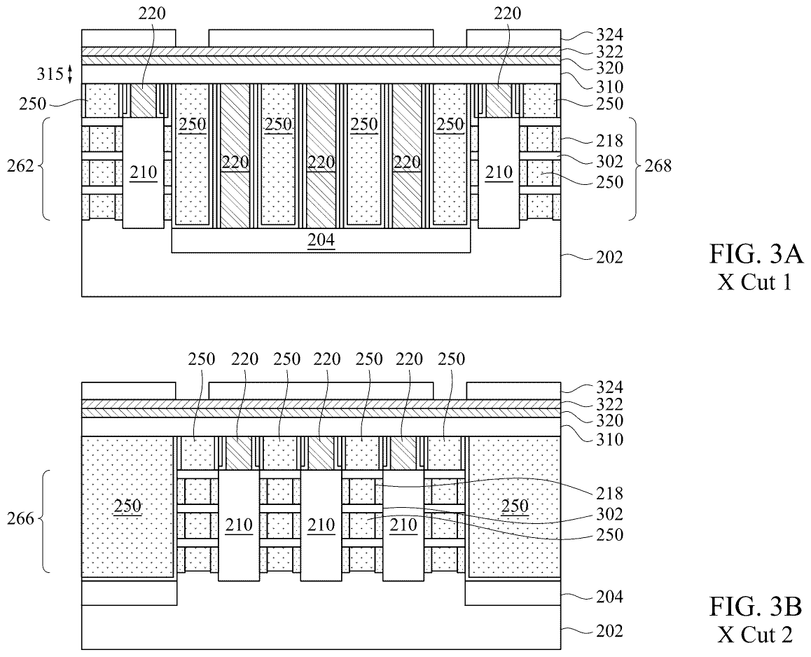

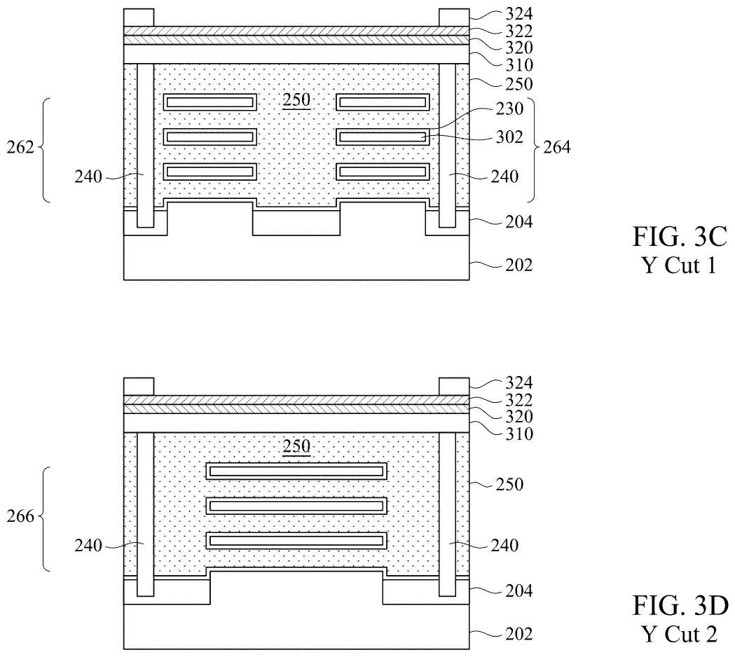

Referring now to step 106 of FIG. 1A as illustrated in FIGS. 3A-3D, a hard mask layer 310 having thickness 315 is applied upon the gate electrodes 250 and the ILD regions 220. In some embodiments, the thickness 315 of the hard mask layer is from about 600 angstroms to about 900 angstroms, or from about 700 angstroms to about 800 angstroms.

In optional step 108 of FIG. 1A, a bottom layer 320 and/or a middle layer 322 can be applied over the hard mask layer 310. A spin-on-carbon (SoC) material is suitable for the bottom layer. A spin-on-glass material is commonly used for the middle layer. When used, the combination of the hard mask layer, the bottom layer, and the middle layer results in a tri-layer patterning etch system, which allows for better control of subsequent etching. Then, in step 110 of FIG. 1A, a photoresist (PR) layer 324 is applied and patterned. In particular embodiments, extreme ultraviolet (EUV) light having a wavelength of about 13.5 nm is used for patterning, as this permits smaller feature sizes to be obtained. If the bottom layer and middle layer are not used, then the PR layer would be applied directly to the hard mask layer 310. The resulting structure is illustrated in FIGS. 3A-3D. It can be seen that the PR layer 324 is patterned to expose two gate electrodes 250 in the second region 284, i.e. along line Y2-Y2 of FIG. 2A within or adjacent the jog regions 280. As seen in FIG. 3C, the first fin portion 262 and the second fin portion 264 are exposed. As seen in FIG. 3D, the third fin portion 266 is exposed.

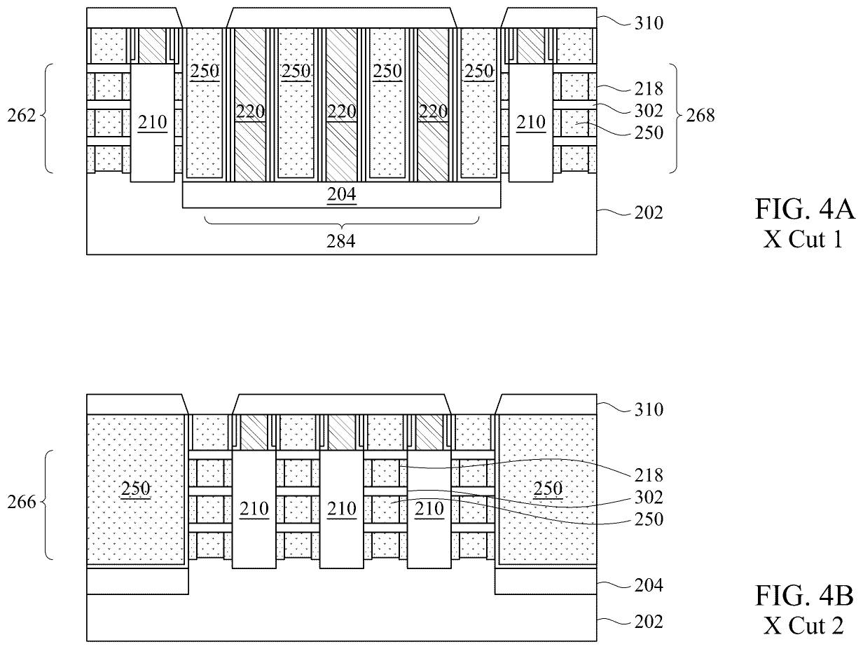

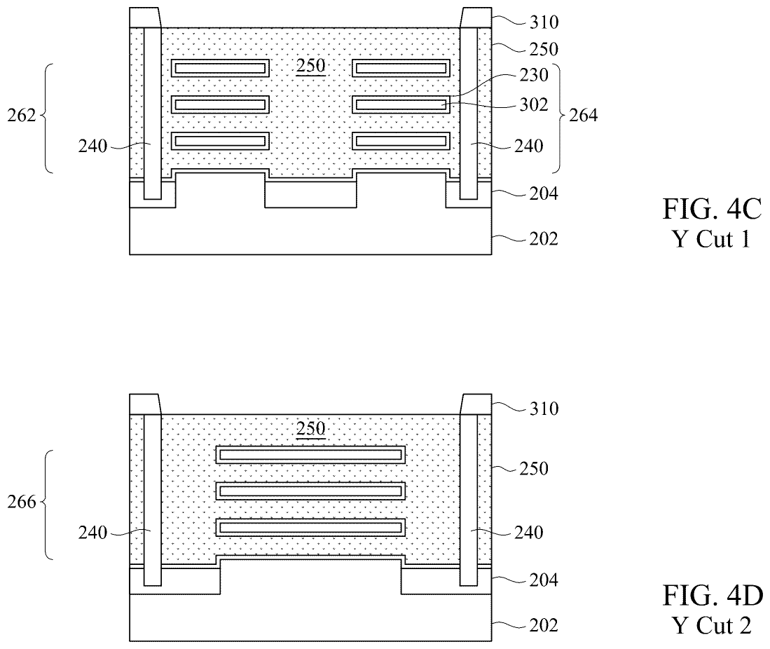

Next, in step 112 of FIG. 1A, the hard mask layer 310 is patterned. This may be done, for example, by dry etching. This may be referred to as Hard Mask Open (HMO). When present, the middle layer 322 and the bottom layer 320 are etched through first, using appropriate etchants. After removal of the bottom layer, the middle layer, and the PR layer, the resulting structure is seen in FIGS. 4A-4D. It can be seen that the hard mask layer 310 is patterned to expose two gate electrodes 250 in the second region 284, i.e. along line Y2-Y2 of FIG. 2A within or adjacent the jog regions 280.

Next, in step 114 of FIG. 1A, etching is performed to remove the gate material in any gate regions within or adjacent the jog regions 280. Any gate dielectric layer that is present is also removed. Here, the gate regions are the gate electrodes 250 are removed. As indicated in step 116 of FIG. 1A, at least one semiconducting fin portion in the jog region is exposed. As seen in FIG. 4C, the first fin portion 262 and the second fin portion 264 in the jog region are exposed after the gate electrode 250 is removed. Similarly, as seen in FIG. 4D, the third fin portion 266 in the jog region is exposed after the gate electrode 250 is removed. These fin portions are on the front side of the substrate.

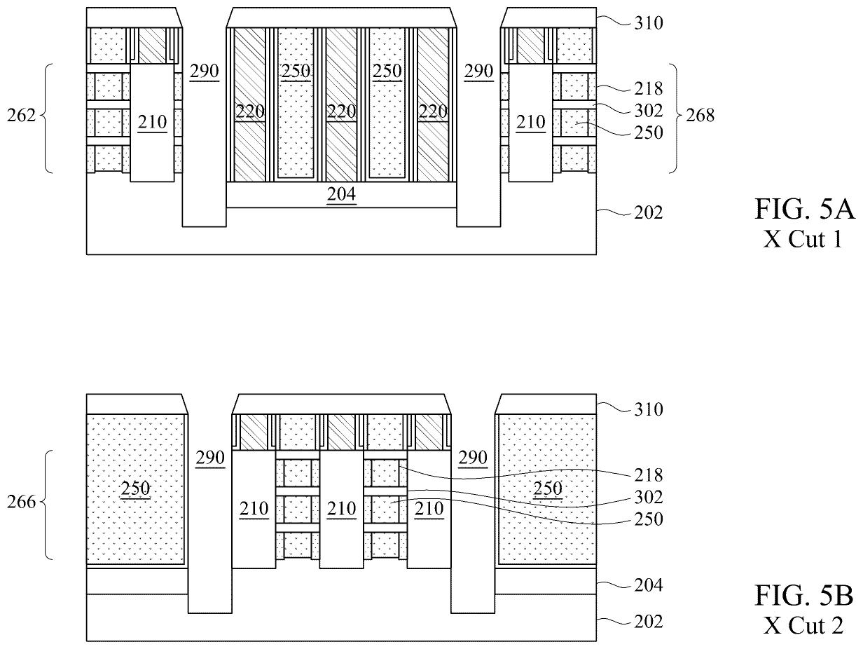

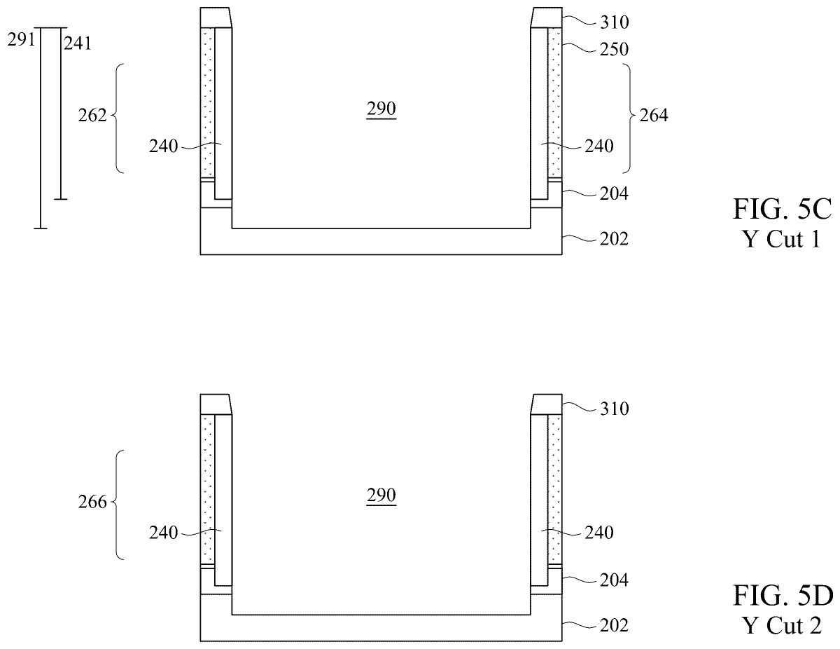

Then, in step 118, the exposed semiconducting fin portions are etched away as well. As a result, as seen in FIGS. 5A-5D, a first trench 290 is formed in the jog region. Illustrated here are two first trenches 290, which are empty or hollow. Referring to FIG. 5C, the first trench 290 has a depth 291. The CMG trench 240 has a CMG depth 241. In particular embodiments, the first trench depth 291 is equal to or greater than the CMG depth 241, and in more specific embodiments is greater than the CMG depth 241. It is noted that this etching only occurs within or adjacent the jog region(s) 280 (see FIG. 2A), and does not occur over the entire second region 284. In addition, while the first trench is illustrated as having a uniform depth, this is not required and may not occur due to the use of multiple etching steps for the different layers.

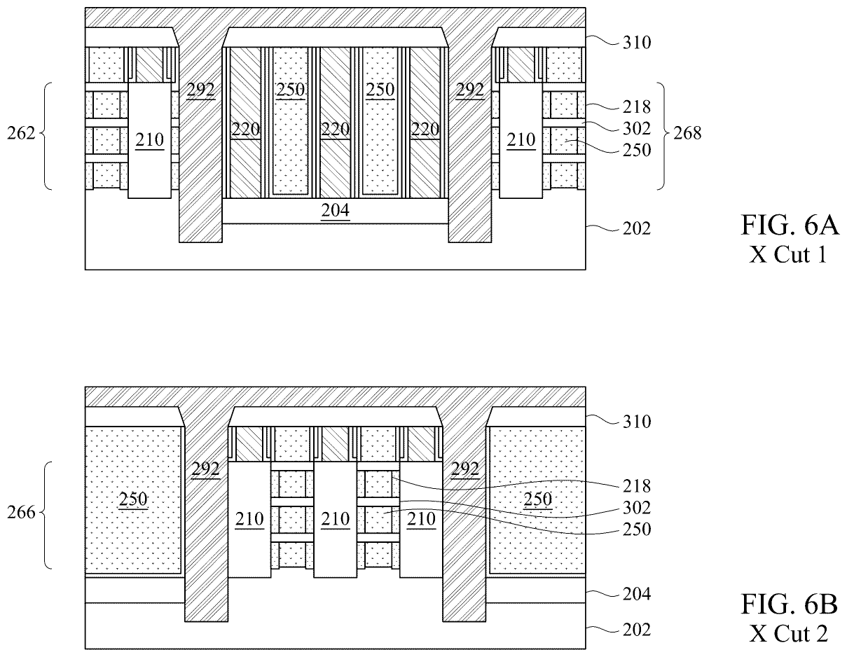

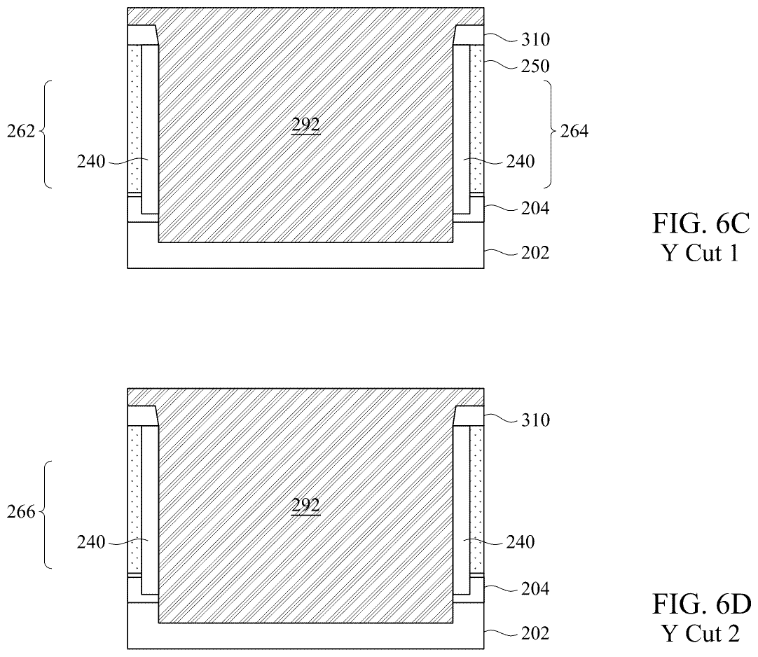

Then, in step 120 of FIG. 1A, the first trench(es) 290 is filled (or refilled) with at least one dielectric material to form a dielectric trench 292. This may be performed by deposition, for example. The resulting structure is illustrated in FIGS. 6A-6D. As seen by comparing FIG. 6C and FIG. 6D, the fin portions 262, 264 in the first region are now electrically isolated from the fin portions 266 in the second region by the dielectric trench 292, which extends beyond the sides of the fin portions 262, 264.

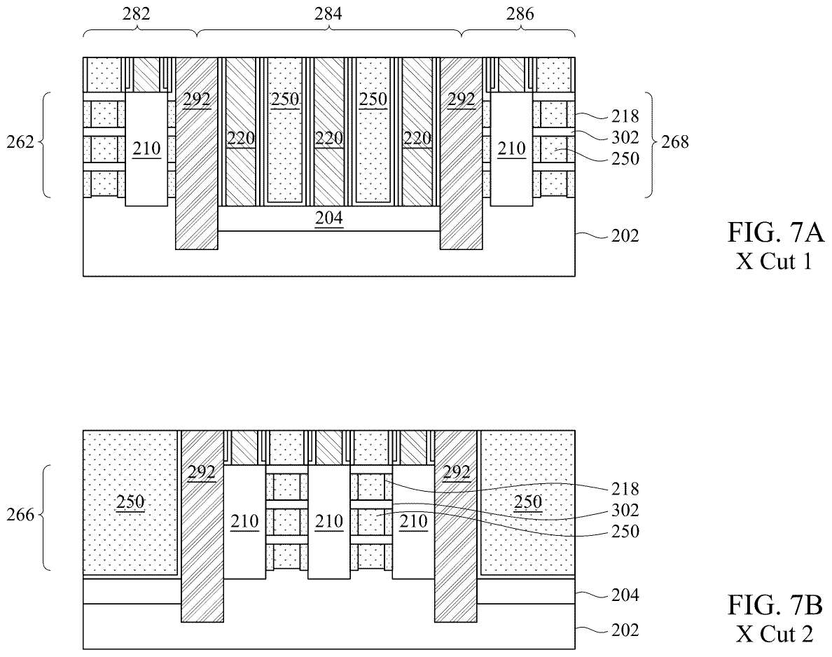

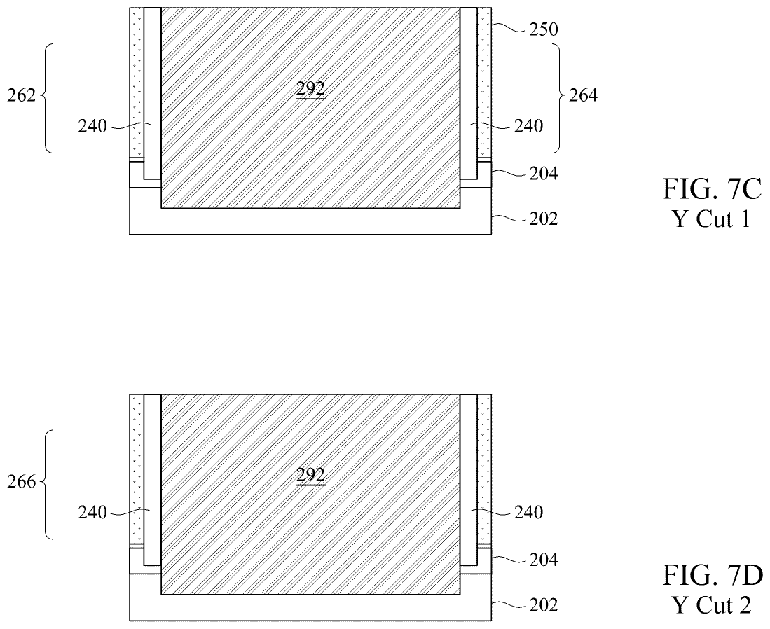

Continuing, then, in step 122 of FIG. 1A, the substrate is planarized to remove the overfill dielectric materials and the hard mask layer 310. The resulting structure is illustrated in FIGS. 7A-7D. The remaining gate electrodes 250 in the first region 282, the second region 284, and the third region 286 are now exposed.

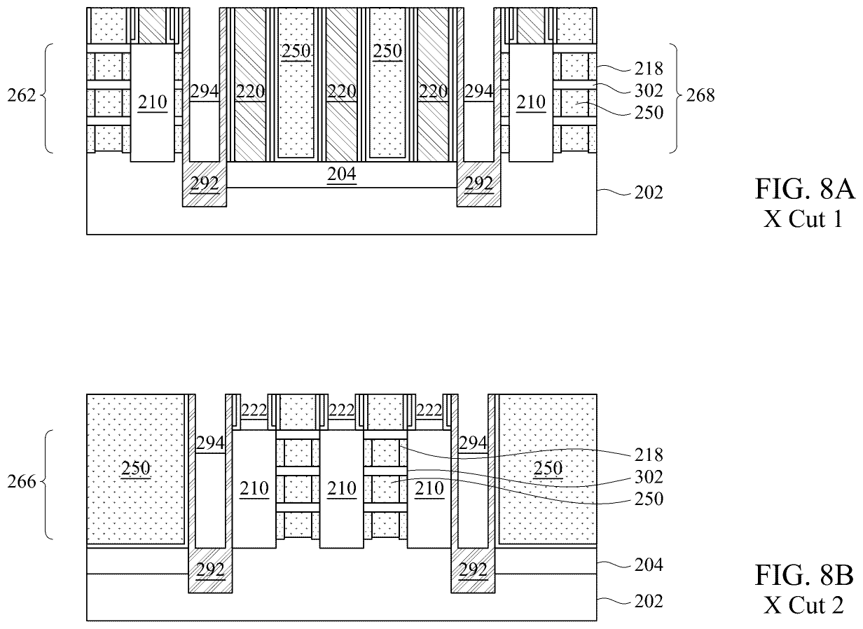

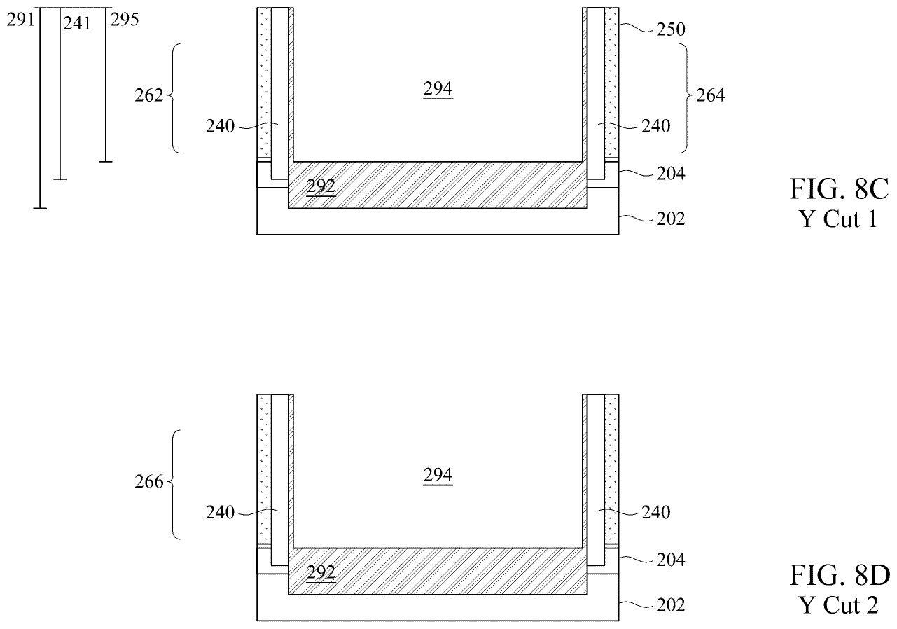

Next, in step 124 of FIG. 1A, a second trench 294 is etched into at least one dielectric trench 292. The resulting structure is shown in FIGS. 8A-8D. As illustrated, portions of the dielectric trench 292 are still present on all sides of the second trench 294, but this is not required.

Referring to FIG. 8C, the dielectric trench 292 also has a depth 291, the CMG trench 240 has a CMG depth 241, and the second trench 294 has an intermediate depth 295. In particular embodiments, the intermediate depth 295 is less than the CMG depth 241. As a result, the intermediate depth 295 is also less than the dielectric trench depth 291.

Although not illustrated here, in optional step 126 of FIG. 1A, a third trench is etched into at least one CMG trench 240. The third trench will also be etched down to the intermediate depth 295.

In optional step 128 of FIG. 1A, and as visible in FIG. 8B, portions of one or more ILD regions 220 can also be etched to form an ILD trench 222. In FIG. 8B, the ILD trenches 222 are formed above one or more source/drain regions 210, but not to their sides, as indicated by the continued presence of the ILD regions 220 in FIG. 8A. In other embodiments, the ILD regions to the sides of the semiconducting fin could be etched away, either alternatively or in conjunction with the ILD region above the source/drain regions, as desired, to form ILD trenches. This may be accomplished with appropriate patterning prior to etching. It is noted that steps 126, and 128 may be performed concurrently with step 124 when the dielectric trench 292 is etched, especially if the dielectric trench 292, the CMG trench 240, and the ILD region(s) 220 are made of the same material. This may be accomplished with appropriate patterning prior to etching.

Although not illustrated here, in optional step 130 of FIG. 1A, etching may be performed to remove an exposed source/drain region 210 and form an S/D trench. Referring to FIG. 8B, the S/D trench would be located below an ILD trench 222.

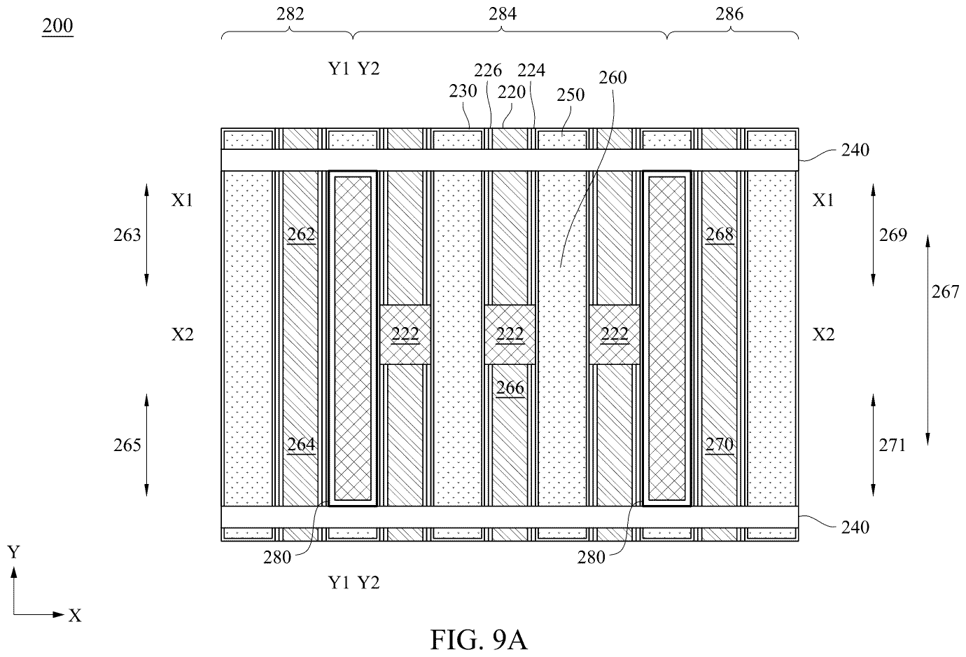

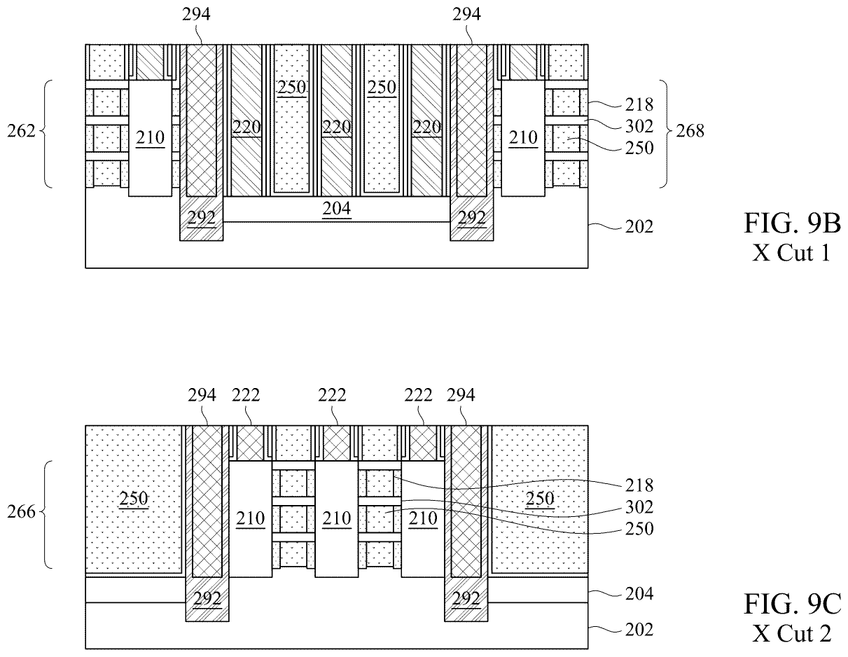

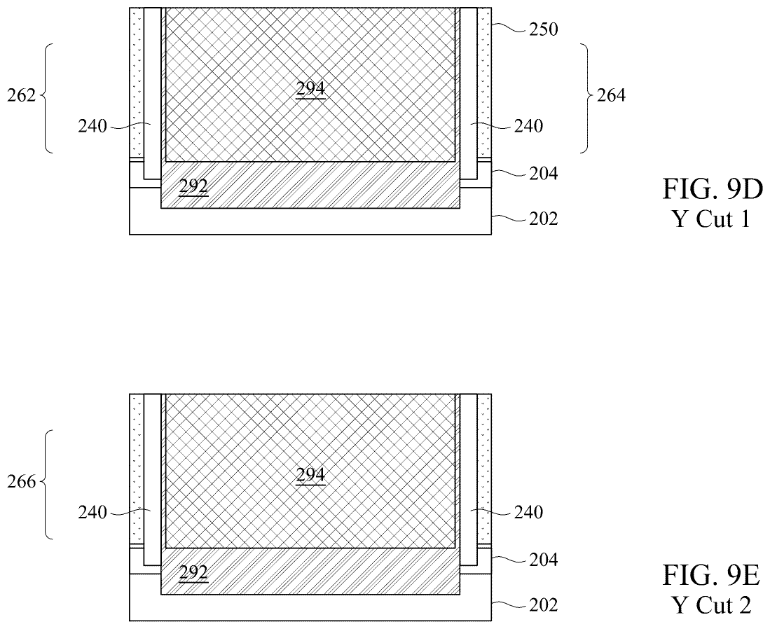

Next, as illustrated in FIGS. 9A-9E, an electrically conductive material is deposited to fill the various trenches and begin forming one or more feedthrough vias (FTVs). In step 132 of FIG. 1A, the second trench 294 is filled with the electrically conductive material. In optional step 134, the ILD trench 222 and the S/D trench are filled with the electrically conductive material. In optional step 136, the third trench in the CMG trench is filled with the electrically conductive material. Steps 132, 134, and 136 may be performed concurrently. The electrically conductive material is usually a metal. The dielectric trench 292 still separates the metal-filled second trench from the substrate to reduce metal migration into the substrate.

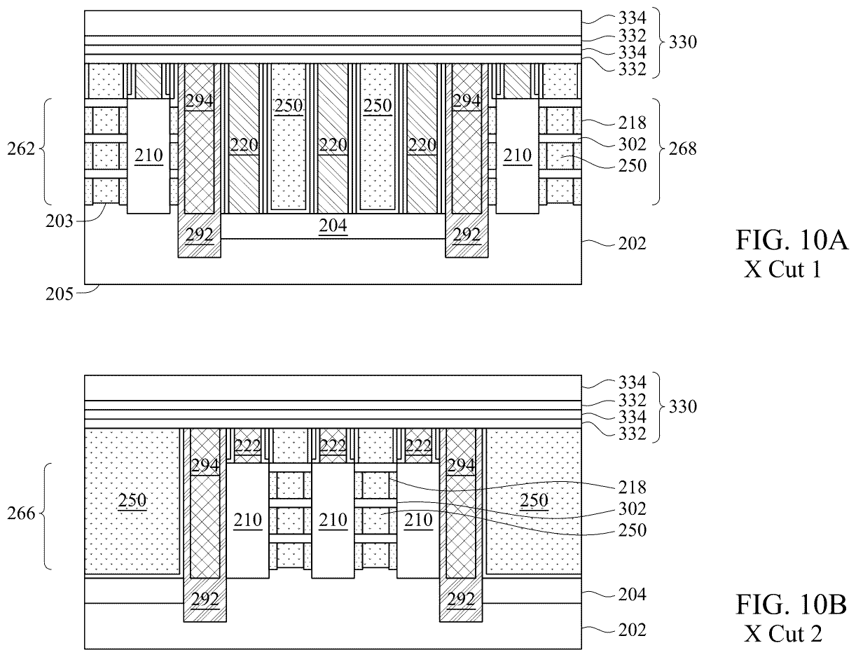

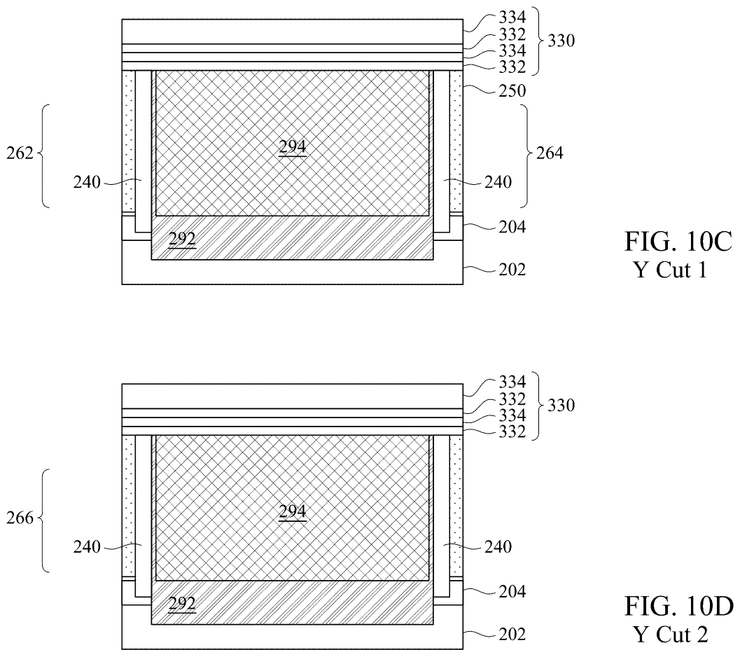

If desired, planarization may be performed again to remove excess material. Then, in step 138 of FIG. 1A and as illustrated in FIGS. 10A-10D, front side routing 330 is formed upon the front side 203 of the substrate. The front side routing 330 is illustrated here as a series of alternating etch stop layers 332 and ILD layers 334. The front side routing 330 is electrically connected to the second trench(es) 294, the ILD trench(es) 222, and the third trench(es) within the CMG trench(es).

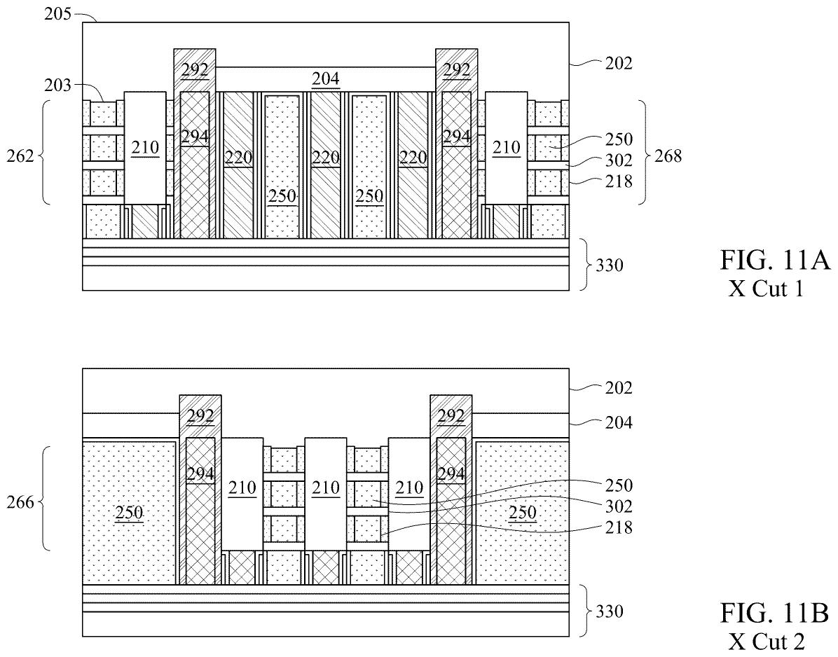

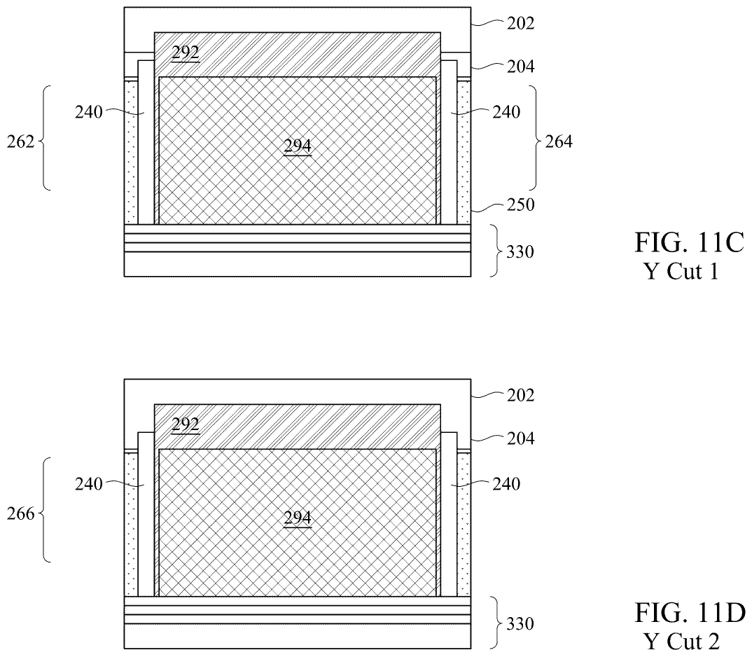

Next, in step 140 of FIG. 1A and as illustrated in FIGS. 11A-11D, the wafer substrate 202 is flipped. This may be done by attaching a carrier wafer (not shown) to the front side routing. The front side 203 and the back side 205 are indicated in FIG. 11A.

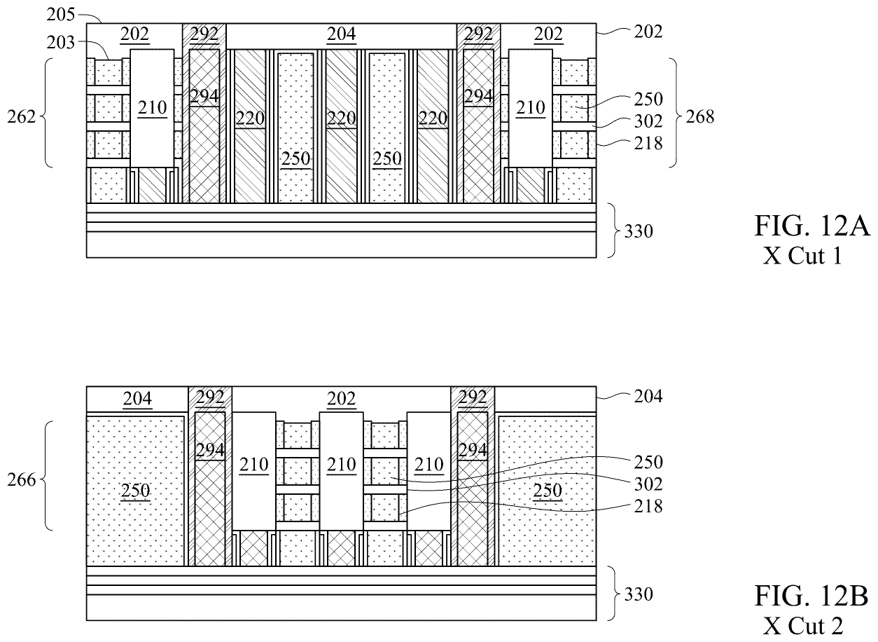

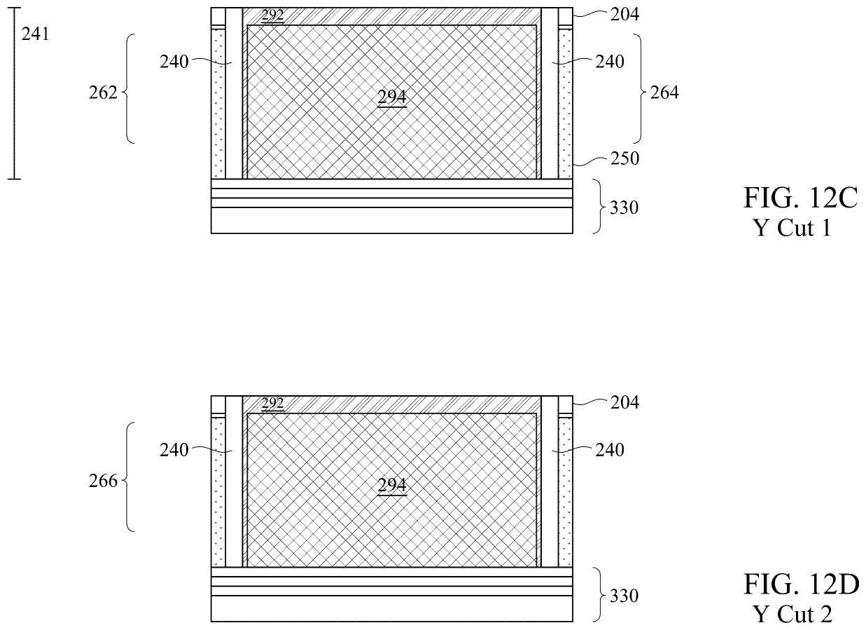

In step 142 of FIG. 1A and as illustrated in FIGS. 12A-12D, the back side 205 of the substrate 202 is planarized to expose the CMG trenches 240. Put another way, the back side is planarized to the CMG depth 241, as indicated in FIG. 12D. This may be done, for example by CMP or grinding. It is noted that in some embodiments, a CMP stop layer, formed for example from SiGe, may be used. As illustrated here, the substrate may no longer be continuous or present over the entirety of the semiconducting device, depending on the depth of the CMG trenches.

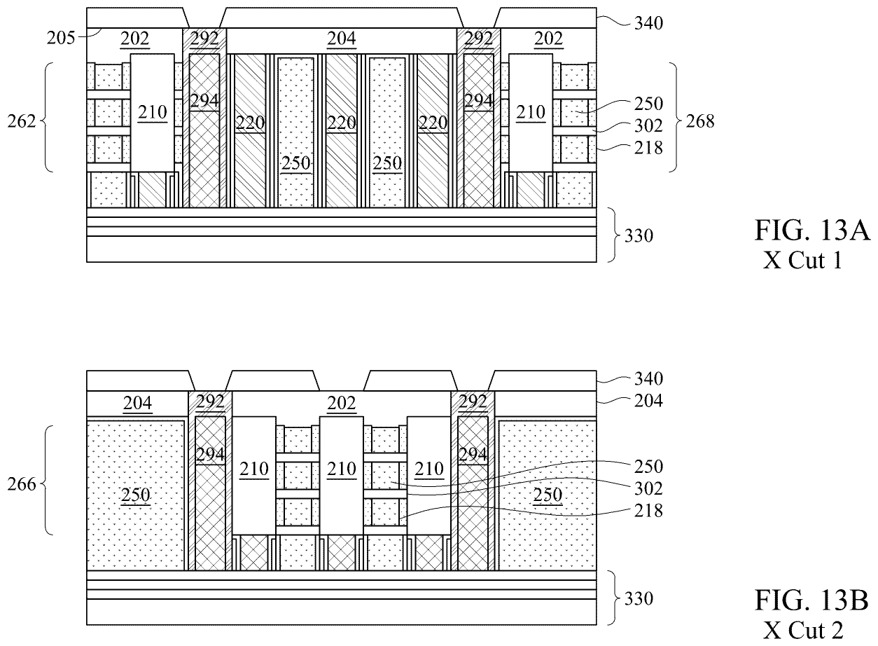

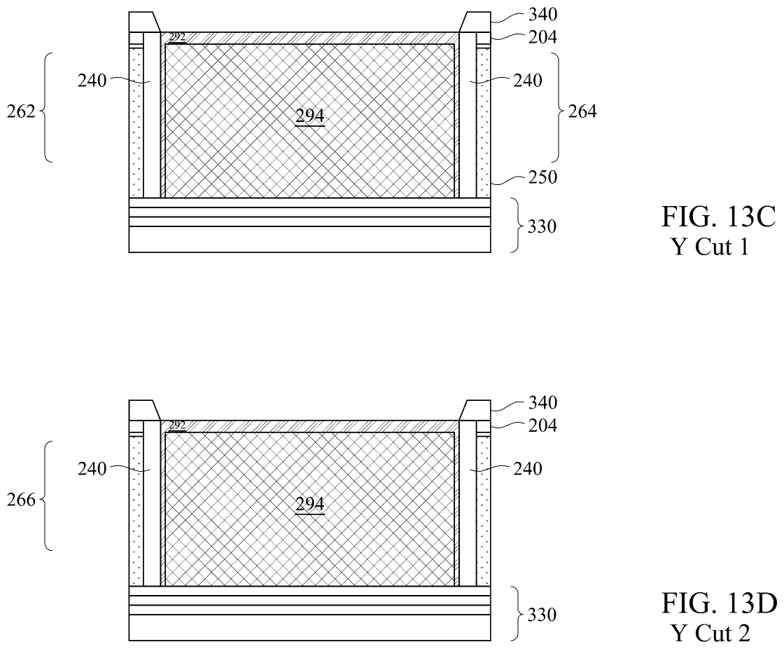

Then, in step 144 of FIG. 1A and as illustrated in FIGS. 13A-13D, a hard mask layer 340 is applied to the back side 205 and patterned. Here, the hard mask layer 340 is patterned to expose the second trench(es) 294 and one of the source/drain regions 210 located between the second trench(es).

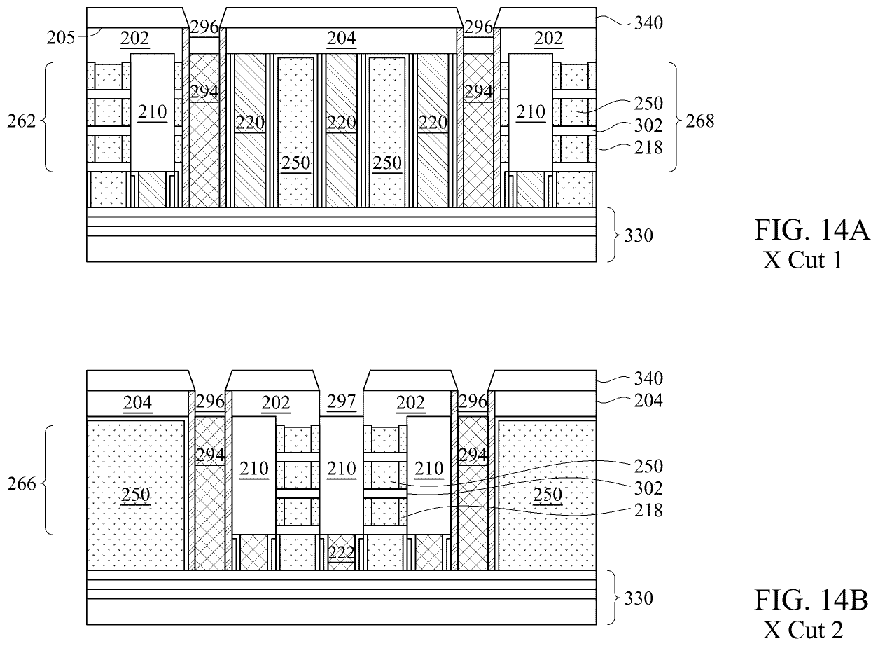

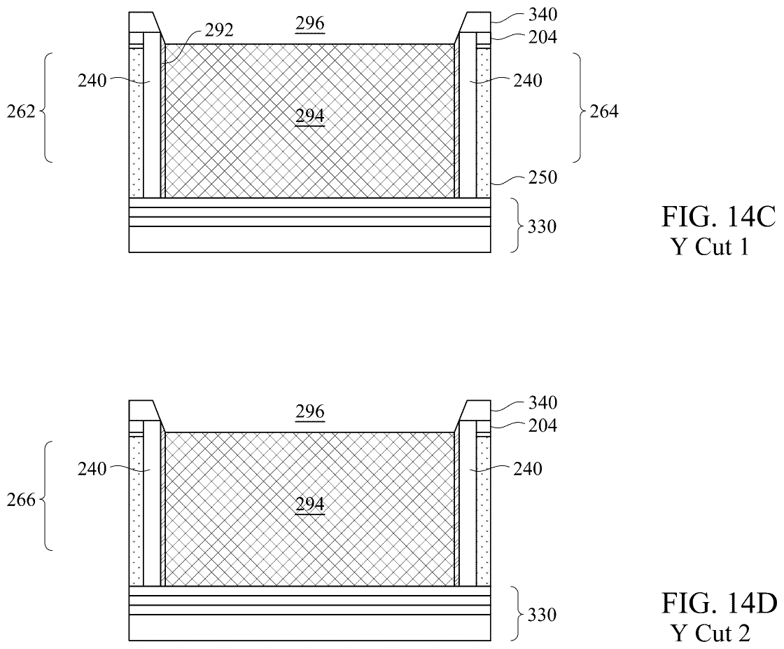

Referring now to FIGS. 14A-14D, in step 146 of FIG. 1A, the dielectric trench 292 is etched from the back side 205 to expose the second trench 294. A backside volume 296 is formed. In optional step 148, the back side 205 is etched to expose one or more S/D regions 210. An S/D backside volume 297 is thus formed. In optional step 150, the CMG trench is etched from the back side to expose the third trench. A CMG backside volume is thus formed. These steps 146, 148, 150 can be performed concurrently if desired. They may be performed using the same mask or different masks.

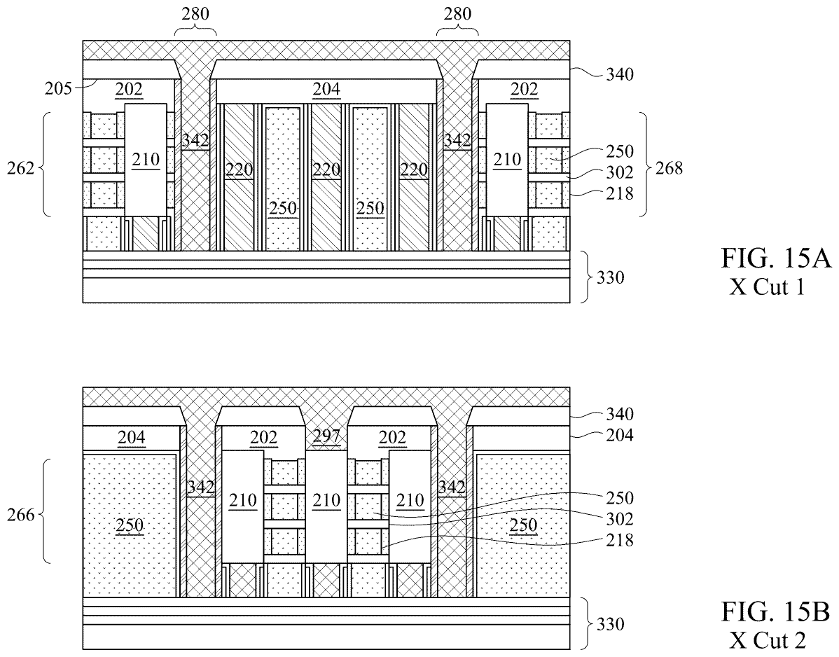

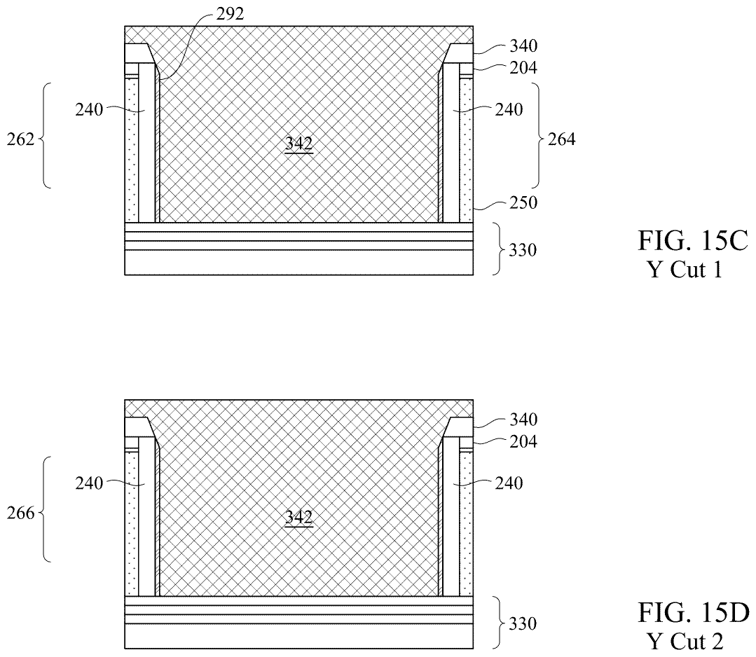

Referring now to FIGS. 15A-15D, in step 150 of FIG. 1A, the backside volume is filled with the electrically conductive material. In optional step 152, the S/D backside volume 297 is filled with the electrically conductive material. In optional step 154, the CMG backside volume is filled with the electrically conductive material. These steps 152, 154, 156 can be performed concurrently if desired. As seen here, a CPODE FTV 342 is thus formed in the jog region 280 (see also FIG. 9A). The CPODE FTV extends in the latitudinal direction (i.e. along the Y-axis).

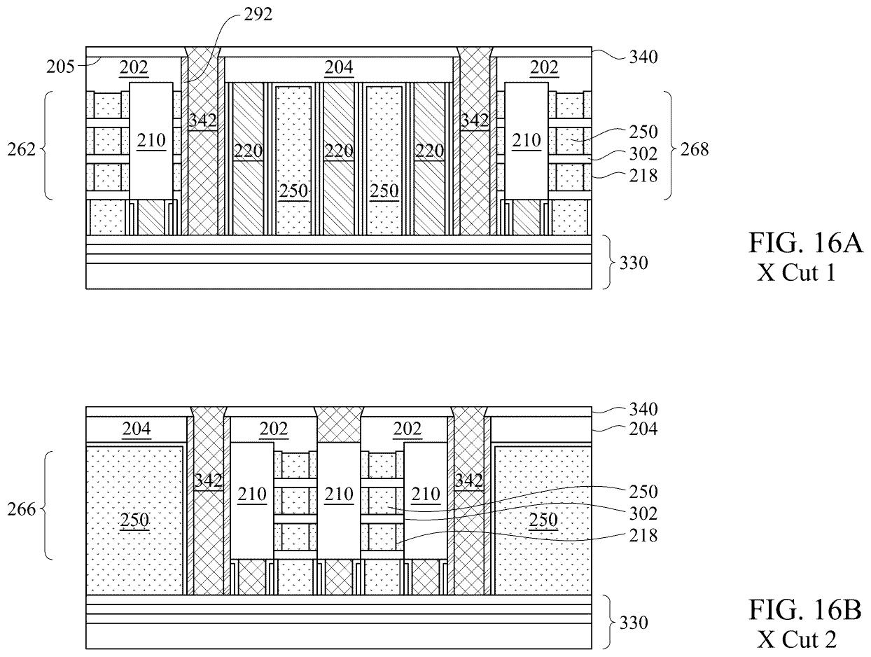

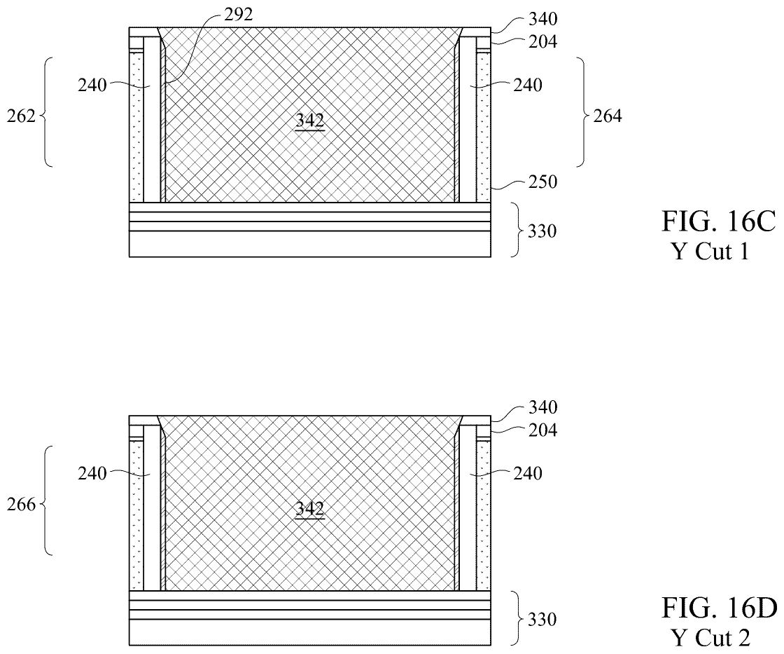

Continuing, in step 158 of FIG. 1A and as illustrated in FIGS. 16A-16D, the back side 205 of the substrate is planarized to remove excess electrically conductive material. The hard mask layer 340 does not need to be completely removed, and is illustrated as still being present after the planarization.

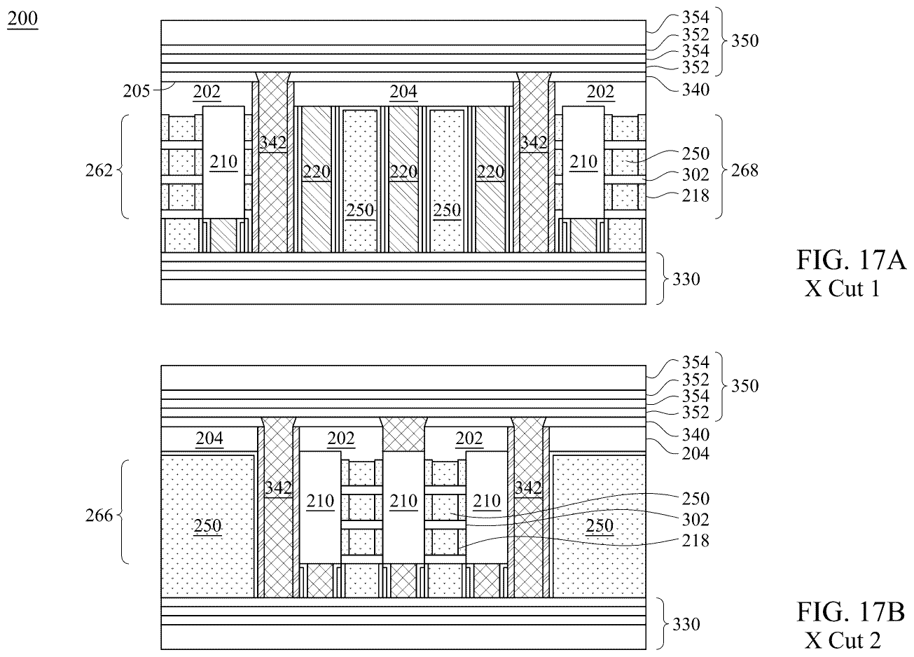

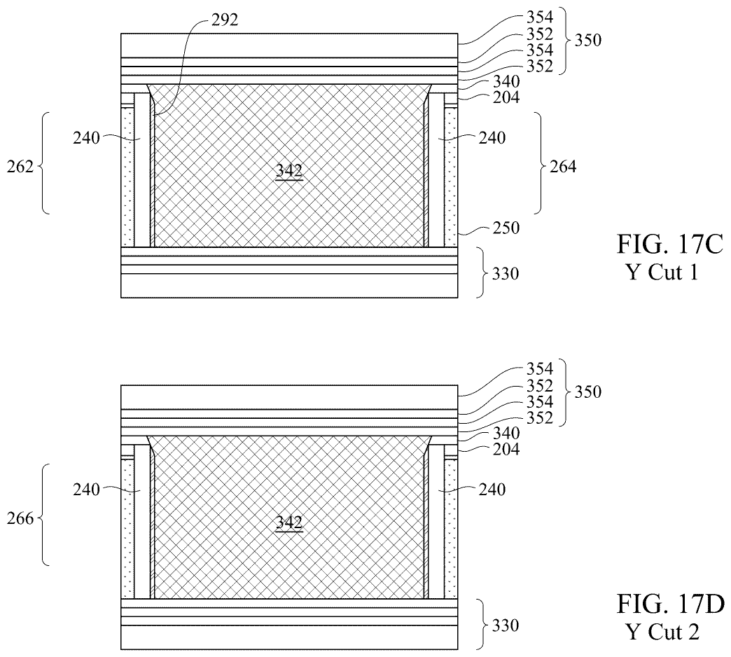

Next, in step of FIG. 1A and as illustrated in FIGS. 17A-17D, back side routing 350 is formed upon the back side 205 of the substrate. The back side routing 350 is illustrated here as a series of alternating etch stop layers 352 and ILD layers 354. The front side routing 330 and the back side routing 350 are electrically connected to the CPODE FTV 342. A semiconducting device or integrated circuit 200 is thus formed that has a feedthrough via 342 from the front side to the back side of the substrate.

It is noted that the method of FIG. 1A and FIGS. 2A-17D are illustrated with respect to a substrate in which the gate electrodes are already formed. It is also possible for the method to be performed on a partially-completed substrate that has dummy gates which have not yet been replaced with the gate electrodes. In that situation, steps 106-120 would be performed, and the dielectric trench would be formed. In particular, in step 114, the gate material that is removed would be the dummy gate, as well as any dummy gate oxide material. After step 120 is completed, the dummy gates would be removed and replaced with the gate electrodes. Then, CMG trenches 240 would be formed and filled with dielectric material. Steps 122-160 could then be performed. Again, embodiments where a CPODE FTV is formed only one jog region are contemplated as being within the scope of the present disclosure.

It is also noted that generally, steps 124, 132, 146, and 152 describe replacing the dielectric trench 292 with metal to form a CPODE FTV 342 by replacing part of the dielectric trench from the front side, and then replacing the remainder of the dielectric trench from the back side. However, this is not required. The dielectric trench may be replaced entirely from the front side, or replaced entirely from the back side. Thus, in step 124 (see FIGS. 8A-8D), the second trench could be etched down to the CMG depth 241 rather than the intermediate depth 295, and steps 146 and 152 would not be performed. Alternatively, steps 124 and 132 do not have to be performed, and in step 146 (see FIGS. 14A-14D), the dielectric trench could be etched to an etch stop layer of the front side routing 330.

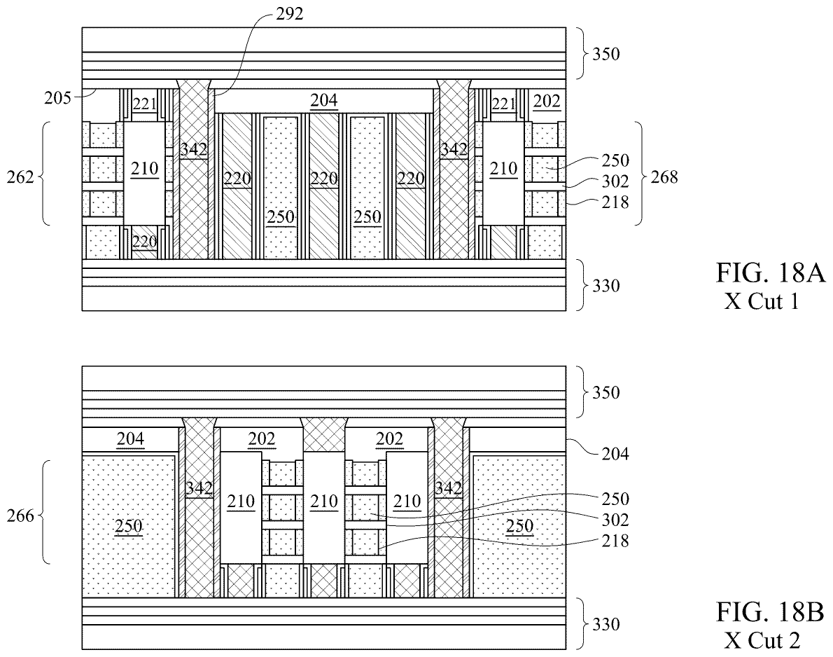

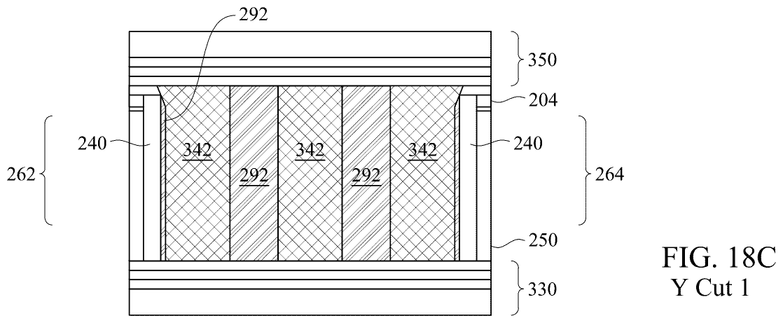

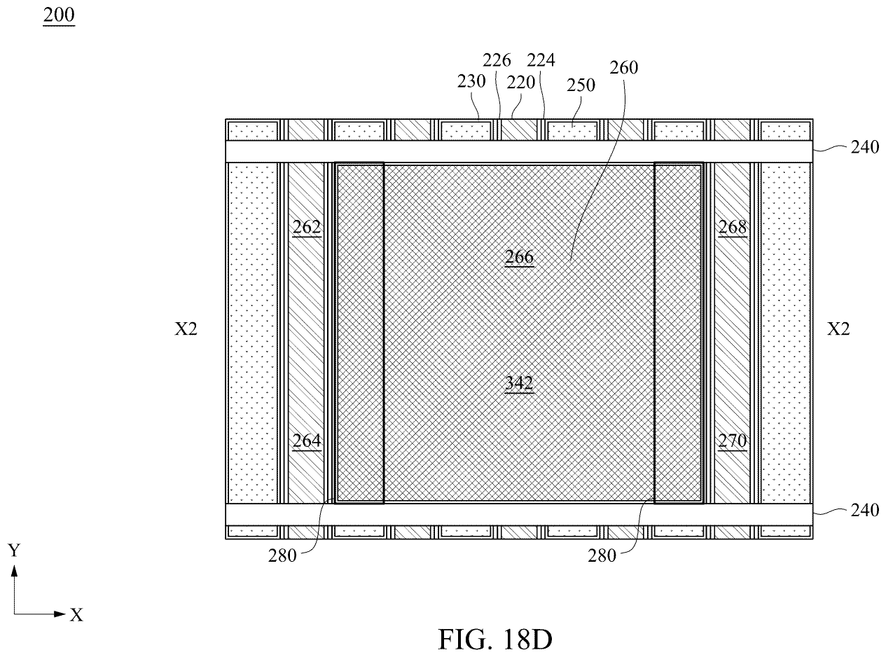

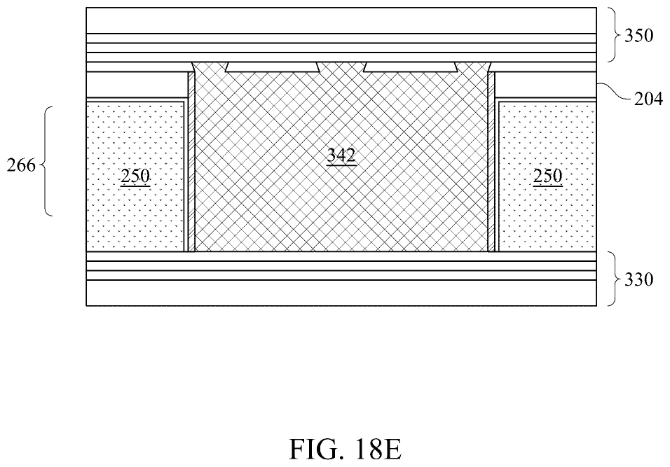

FIG. 18A is an X-axis view of a first variation of the semiconducting device, showing the substrate along line X1-X1 of FIG. 9A. In this embodiment, the source/drain region 211 can be contacted from either side of the substrate, as indicated by the presence of ILD region 220 contacting front side routing 330 and ILD region 221 contacting the back side routing 350.

FIG. 18B is an X-axis view of a second variation of the semiconducting device, showing the substrate along line X2-X2 of FIG. 9A. In this embodiment, step 130 of FIG. 1A was performed to remove the source/drain region 210. As a result, another FTV 344 is formed through the semiconducting fin 260 of FIG. 1A. Depending on the dimensions of the semiconducting fin 260, more than one such FTV 344 can be formed by removal of a source/drain region.

FIG. 18C is a Y-axis view of a third variation of the semiconducting device, showing the substrate along line Y1-Y1 of FIG. 9A. Referring back to FIG. 7C and FIG. 8C, instead of forming one second trench 294 in the dielectric trench 292, multiple second trenches are formed. As a result, once filled with electrically conductive material, as seen in FIG. 18C, multiple FTVs 342 are formed through the dielectric trench 292 in the jog region 280. Three FTVs are illustrated here, though any number may be formed depending on the dimensions of the dielectric trench.

FIG. 18D and FIG. 18E together illustrate a fourth variation of the semiconducting device. As illustrated here, the other components within semiconducting fin portion 266 have been entirely removed, and the CPODE FTV 342 extends through at least one jog region and through the semiconducting fin portion 266. Put another way, the CPODE FTV 342 fills the portion 266, or the portion having the greatest width. It is contemplated that the various structures 210, 218, 220, 224, 226, 250, 302 illustrated in this portion in the prior figures can be removed by etching, or intentionally not previously formed in this portion.

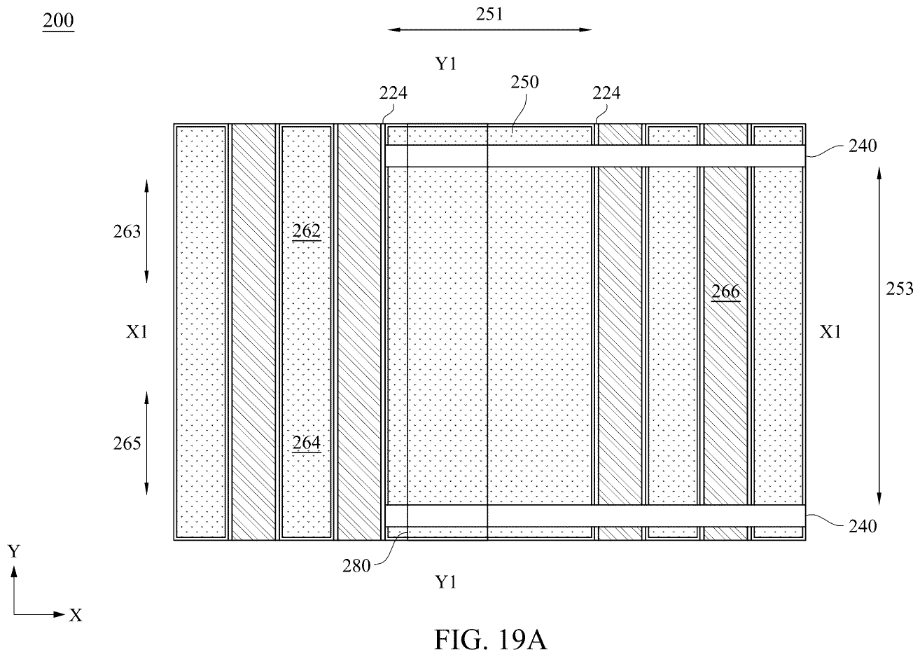

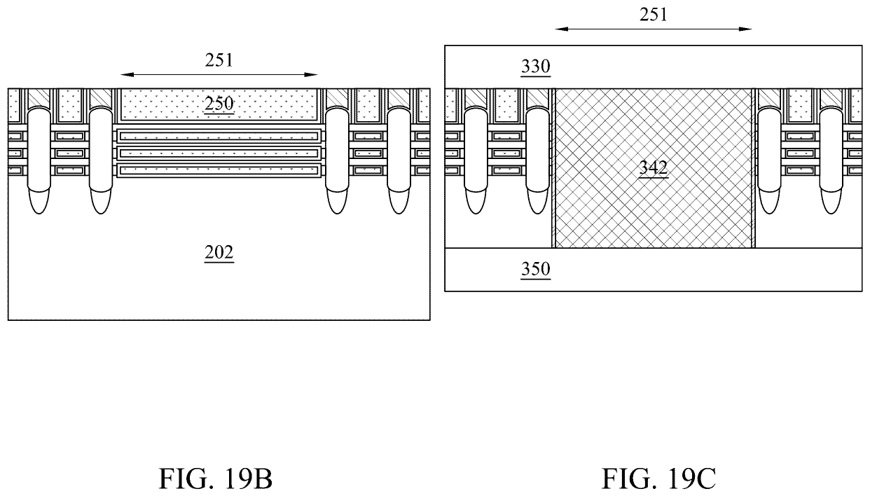

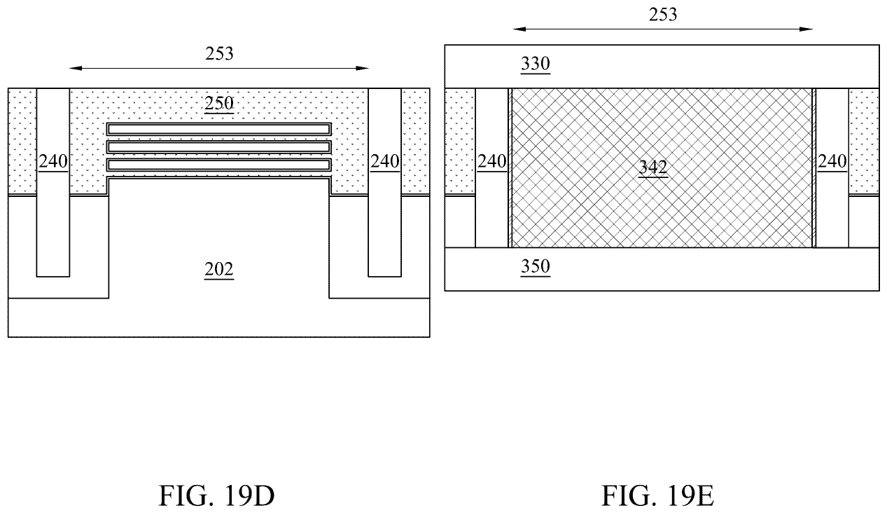

The dimensions of the CPODE FTV 342 can vary as desired. FIGS. 19A-19E illustrate a variation compared to FIG. 1A, with a larger gate electrode 250 within the jog region 280 formed between semiconducting fin portions 262, 264, 266. The gate electrode 250 has a length 251 along the X-axis and a width 253 along the Y-axis. The length is measured between the low-k dielectric spacers 224 on either side of the gate electrode 250. The width 253 is measured between the CMG trenches 240. The length and width may vary independently, and there is no requirement that the length be greater than the width. In some particular embodiments, the length 251 is 20 nanometers (nm) or higher, perhaps up to 200 nm. In some particular embodiments, the width 251 is 40 nanometers (nm) or higher, perhaps up to 200 nm. Other ranges and values are also within the scope of this disclosure. Higher dimensions reduce electrical resistance.

FIG. 19B and FIG. 19C are both X-axis views taken along line X1-X1. FIG. 19B shows the partially-completed substrate 202, while FIG. 19C shows the substrate after formation of the CPODE FTV 342. FIG. 19D and FIG. 19E are both Y-axis views taken along line Y1-Y1. FIG. 19D shows the partially-completed substrate 202, while FIG. 19E shows the substrate after formation of the CPODE FTV 342. Front side routing 330 and back side routing 350 are also illustrated.

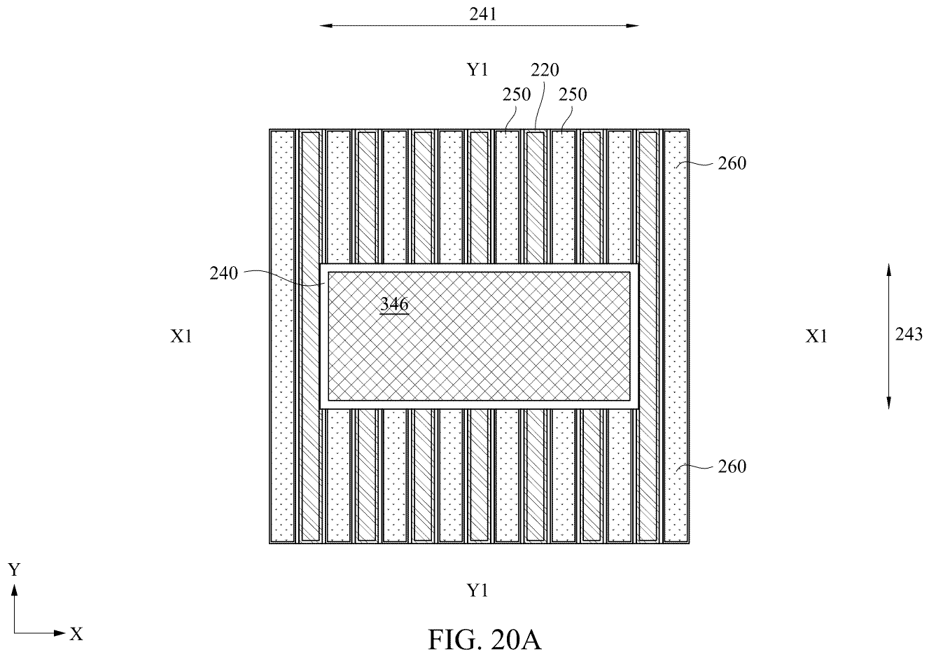

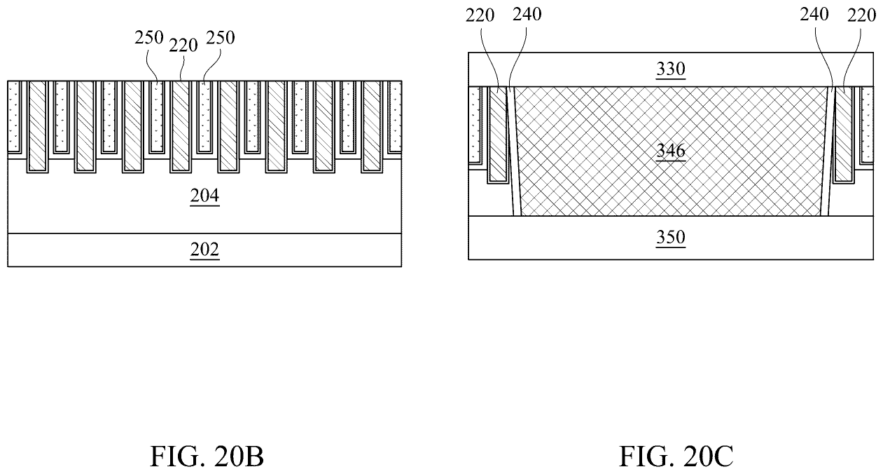

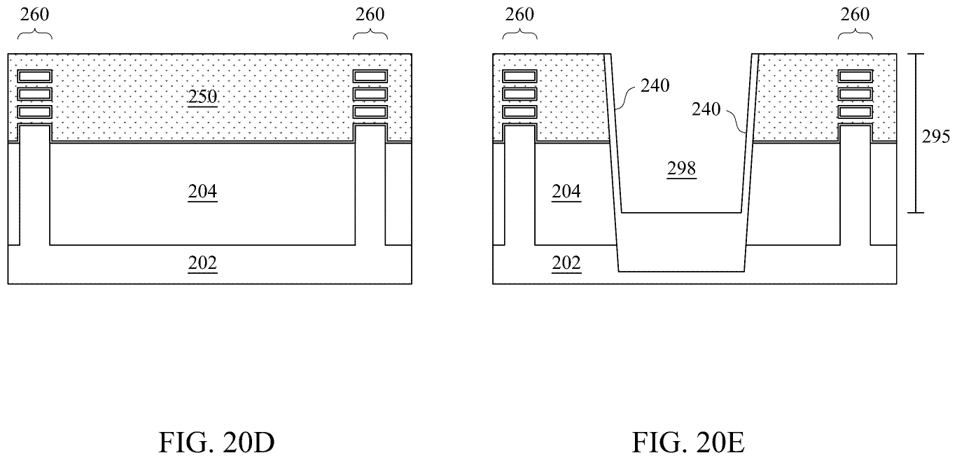

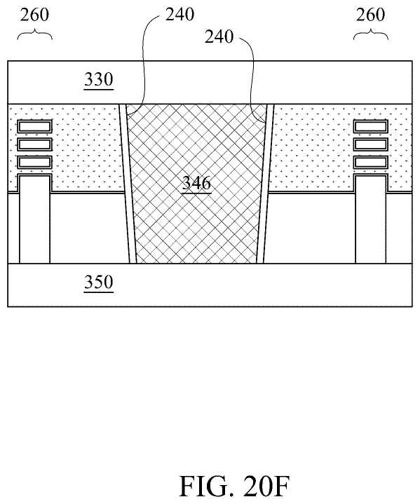

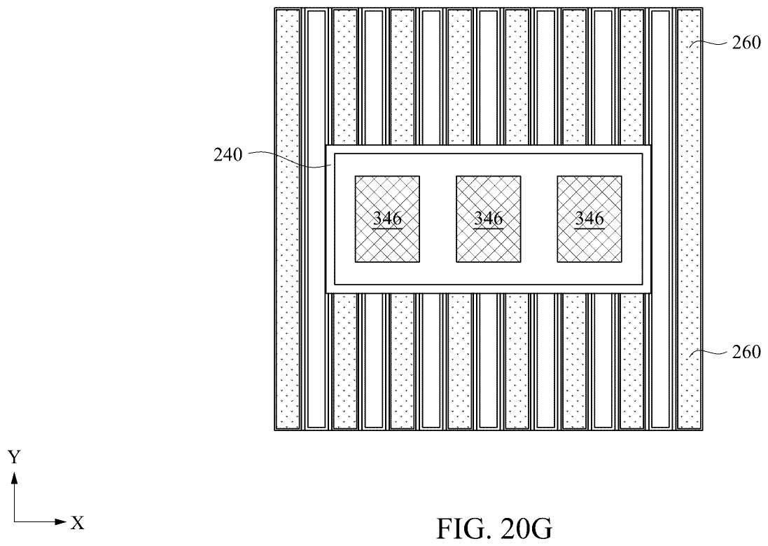

The dimensions of the CMG trench 240 can also vary as desired. FIGS. 20A-20E show a magnified view of a CMG trench 240 containing a CMG feedthrough via 346. The CMG trench has a length 241 along the X-axis and a width 243 along the Y-axis. The length and width may vary independently, and there is no requirement that the length be greater than the width. The CMG trench 240 is located between two semiconducting fins 260, and separates the gate electrodes 250 into two portions, such that each semiconducting fin operates as a separate transistor. The CMG trench 240 is filled with a dielectric material.

FIG. 20B and FIG. 20C are both X-axis views taken along line X1-X1 of FIG. 20A. FIG. 20B shows the partially-completed substrate 202. Here, the STI layer 204 is also visible upon the substrate 202. ILD regions 220 and gate electrodes 250 alternate over the STI layer. FIG. 20C shows the substrate after formation of the CMG FTV 346. The CMG trench 240 separates the FTV 346 from the ILD regions 220. Front side routing 330 and back side routing 350 are also illustrated.

FIG. 20D-20F are Y-axis views taken along line Y1-Y1 of FIG. 20A, and show the formation of the CMG FTV 346. FIG. 20D shows the partially-completed substrate 202. The gate electrode 250 is present between two semiconducting fins 260.

FIG. 20E shows the substrate 202 after step 126 of FIG. 1A has been performed to form a third trench 298 within the CMG trench 240. The dielectric material of the CMG trench is present on all sides of the empty third trench. The third trench 298 is etched down to the intermediate depth 295.

FIG. 20F shows the substrate after steps 136, 150, and 156 of FIG. 1A have been performed to form the CMG FTV 346 within the CMG trench 240. Front side routing 330 and back side routing 350 are also illustrated.

FIG. 20G shows another variation. Here, multiple CMG FTVs 346 are formed within a single CMG trench 240. This may be done with appropriate patterning, etching, and filling.

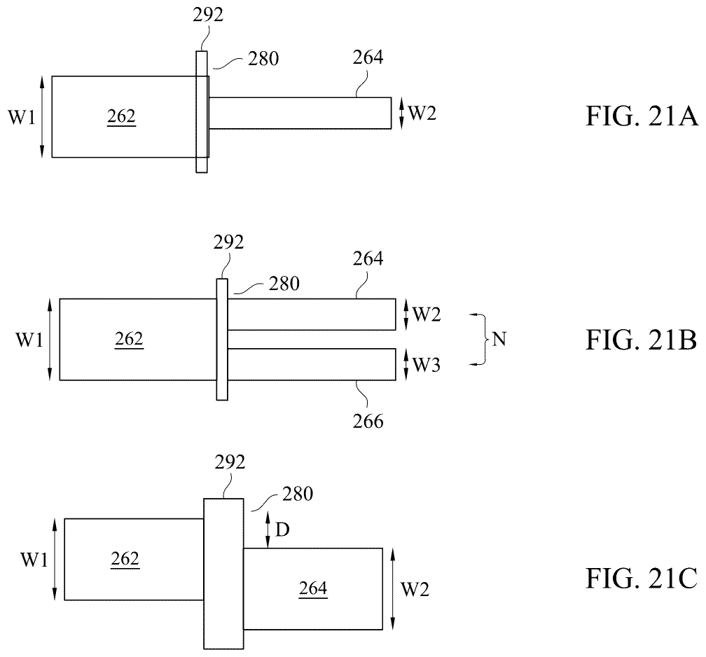

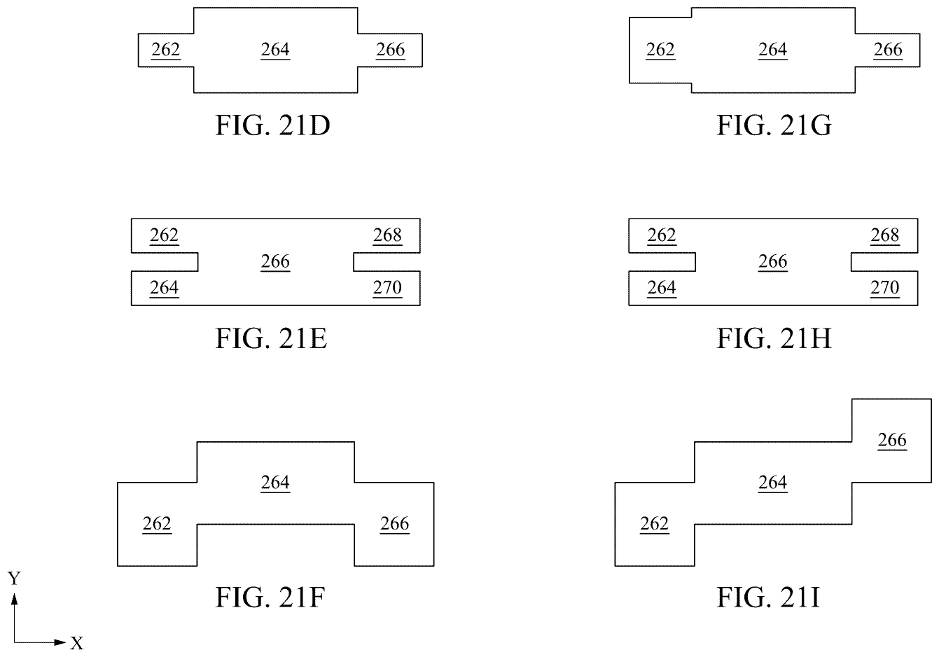

Referring now to FIGS. 21A-21C, the methods of the present disclosure can be applied to any combination of different semiconducting fins/fin portions. Three different combinations are illustrated here.

In FIG. 21A, the first semiconducting fin 262 has nanosheets with a width W1. They are joined at the jog region 280 to a second semiconducting fin 264 which has nanosheets with a different width W2 (W1>W2). Also illustrated here is a dielectric trench 292 that passes through the first semiconducting fin 262 and the nanosheets thereof. The dielectric trench can alternatively pass through the second semiconducting fin 264, or pass through both fins.

FIG. 21B illustrates a combination where one semiconducting fin is joined to multiple semiconducting fins. Here, the first semiconducting fin 262 is joined at one end to a second semiconducting fin 264 and a third semiconducting fin 266. Considered in an alternative manner, one semiconducting fin 262 splits at the jog region 280 into multiple portions 264, 266 in the first region 282, with each portion 264, 266 having a smaller width than the portion 262 of the fin in the second region 284. Here, the dielectric trench 292 is illustrated as passing through the second semiconducting fin 264 and the third semiconducting fin 266.

The first semiconducting fin 262 and its nanosheets have a width W1. Similarly, the second semiconducting fin 264 is designated as having a width W2, and the third semiconducting fin 266 is designated as having a width W3. Here, W1>(W2+W3). Generally the number of multiple semiconducting fins is N≥2.

FIG. 21C illustrates a combination where the first semiconducting fin 262 and the second semiconducting fin 264 have the same width (W1=W2), and the two fins are offset from each other at the jog region 280. The offset difference is indicated with letter D. The dielectric trench 292 is illustrated here as passing through both the first semiconducting fin 262 and the second semiconducting fin 264.

FIGS. 21D-21F show three different symmetric jog patterns that can be formed. In FIG. 21D, first semiconducting fin 262 and third semiconducting fin 266 have the same width. They are on opposite sides of second semiconducting fin 264 (along the X-axis), and are connected at the center of the second semiconducting fin.

In FIG. 21E, first semiconducting fin 262 and second semiconducting fin 264 have the same width. They are both on the left side of third semiconducting fin 266, and are connected at opposite ends of the third semiconducting fin (along the Y-axis). Fourth semiconducting fin 268 and fifth semiconducting fin 270 have the same width. They are both on the right side of third semiconducting fin 266, and are connected at opposite ends of the third semiconducting fin. First semiconducting fin 262 and fourth semiconducting fin 268 have the same width, and are both at the same end of the third semiconducting fin. Second semiconducting fin 264 and fifth semiconducting fin 270 have the same width, and are both at the same end of the third semiconducting fin.

In FIG. 21F, first semiconducting fin 262 and third semiconducting fin 266 have the same width. They are on opposite sides of second semiconducting fin 264, and are both connected at the same end of the second semiconducting fin.

FIGS. 21G-21I show three different symmetric jog patterns that can be formed. In FIG. 21G, first semiconducting fin 262 and third semiconducting fin 266 have different widths. They are on opposite sides of second semiconducting fin 264, and are connected at the center of the second semiconducting fin.

In FIG. 21H, first semiconducting fin 262 and second semiconducting fin 264 have the same width. They are both on the left side of third semiconducting fin 266, and are connected at opposite ends of the third semiconducting fin. Fourth semiconducting fin 268 and fifth semiconducting fin 270 have the same width. They are both on the right side of third semiconducting fin 266, and are connected at opposite ends of the third semiconducting fin. First semiconducting fin 262 and fourth semiconducting fin 268 have different widths, and are both at the same end of the third semiconducting fin. Second semiconducting fin 264 and fifth semiconducting fin 270 have different widths, and are both at the same end of the third semiconducting fin.

In FIG. 21I, first semiconducting fin 262 and third semiconducting fin 266 have the same width. They are on opposite sides of second semiconducting fin 264, and are connected at different ends of the second semiconducting fin.

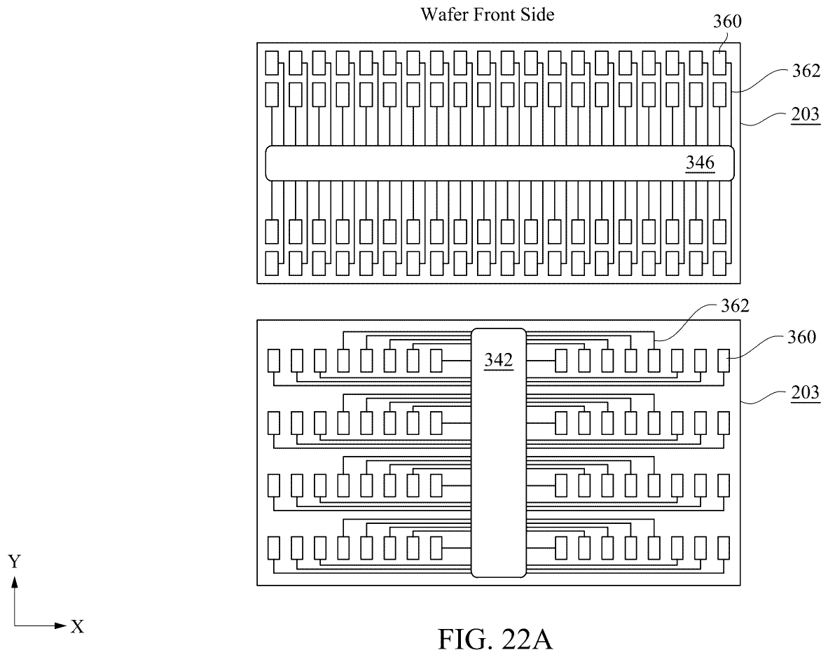

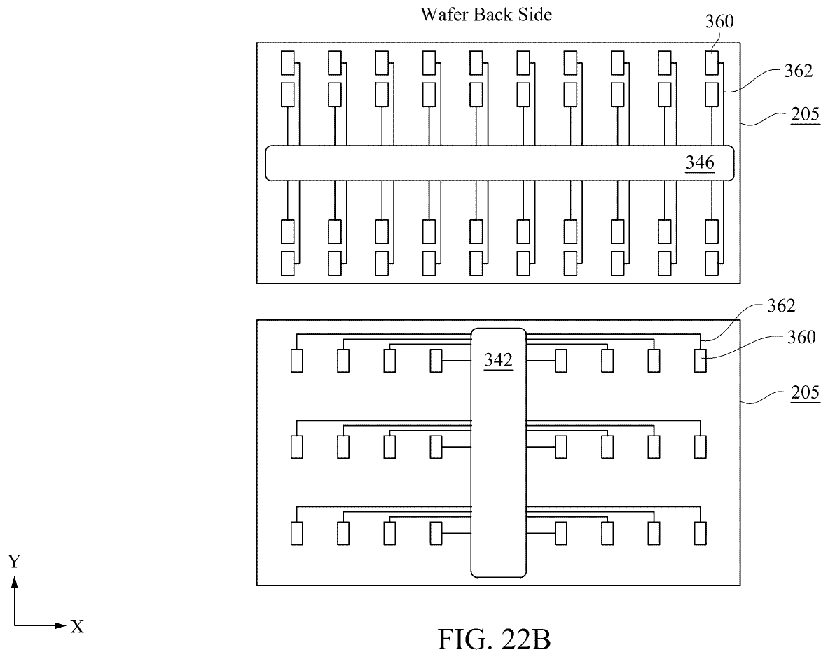

FIG. 22A is a plan view of the wafer front side 203, and FIG. 22B is a plan view of the wafer back side 205. On the front side 203, contacts 360 may be connected to source or drain regions, whereas on the back side 205, the contacts 360 may be connected to source regions. Electrical connections 362 are illustrated as running through a CPODE FTV 342 or a CMG FTV 346 to each contact 360. Electrical communications are more efficient through the CPODE FTV 342 for devices parallel to the CPODE FTV. Similarly, electrical communications are more efficient through the CMG FTV 346 for devices parallel to the CMG FTV.

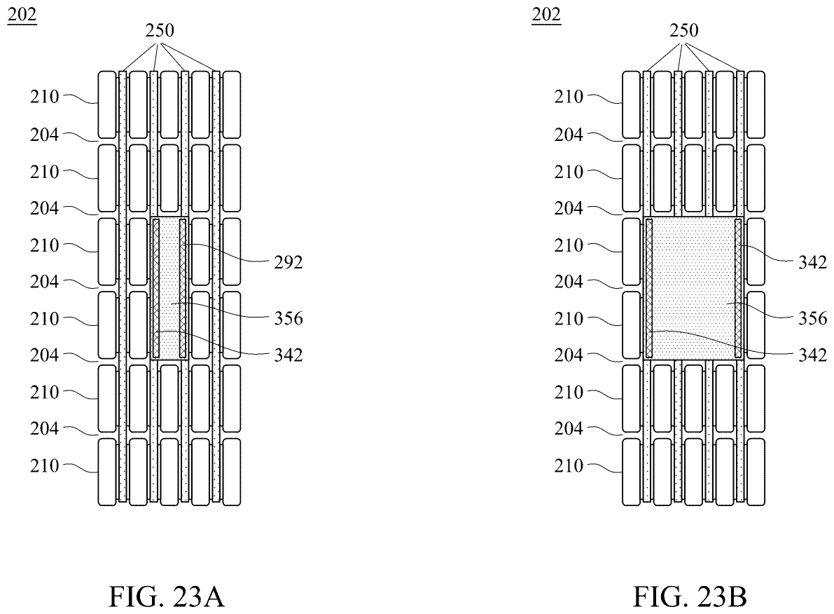

FIG. 23A and FIG. 23B are two different schematic plan views of a wafer substrate 202. In each figure, six rows containing five source/drain (S/D) regions 210 run horizontally, and four gate electrodes 250 run vertically. The S/D regions 210 are separated by STI regions 204. Thus, there are 24 possible transistors in each figure. In FIG. 23A, a feedthrough cell (FTC) 356 is shown taking up the space of two S/D regions. The FTC is formed by replacing the illustrated volume with a dielectric material. S/D regions, gate electrodes, semiconducting material, ILD, etc., are not present within the FTC. Only one CPODE FTV 342 is illustrated within this FTC at a jog region. The other jog region remains filled with a dielectric trench 292 (which was not further processed into a CPODE FTV). In FIG. 23B, the FTC 356 takes up the space of six S/D regions. Two CPODE FTVs 342 are also illustrated within the FTC. This reduces layout-dependent effects and increases pattern density.

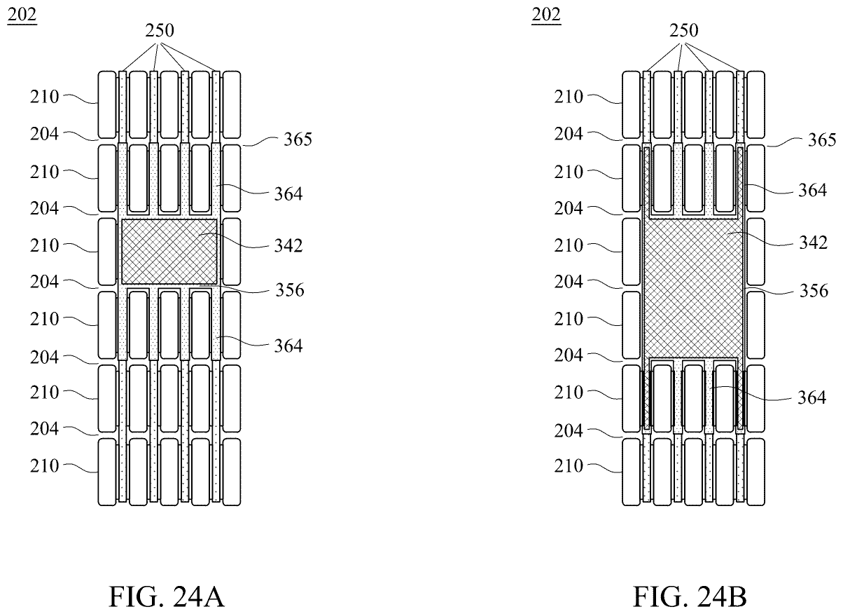

FIG. 24A and FIG. 24B are two different schematic plan views of a wafer substrate 202. Each figure contains six rows of five source/drain (S/D) regions 210, four gate electrodes 250, and STI regions 204. In FIG. 24A, the FTC 356 takes up the space of three S/D regions and cuts across all four gate electrodes 250. The CPODE FTV 342 fills the FTC. In addition, eight CPODE dielectric structures 364 are present and physically connected to the FTC 356. Those eight CPODE dielectric structures replace the gate electrodes and disable the transistors in area 365. A similar structure is illustrated in FIG. 24B, but with a larger FTC 356. In addition, the CPODE FTV 342 is illustrated as extending into four of the CPODE dielectric structures 364. Generally, the CPODE FTV may extend into any number of the CPODE dielectric structures and in any location as desired.

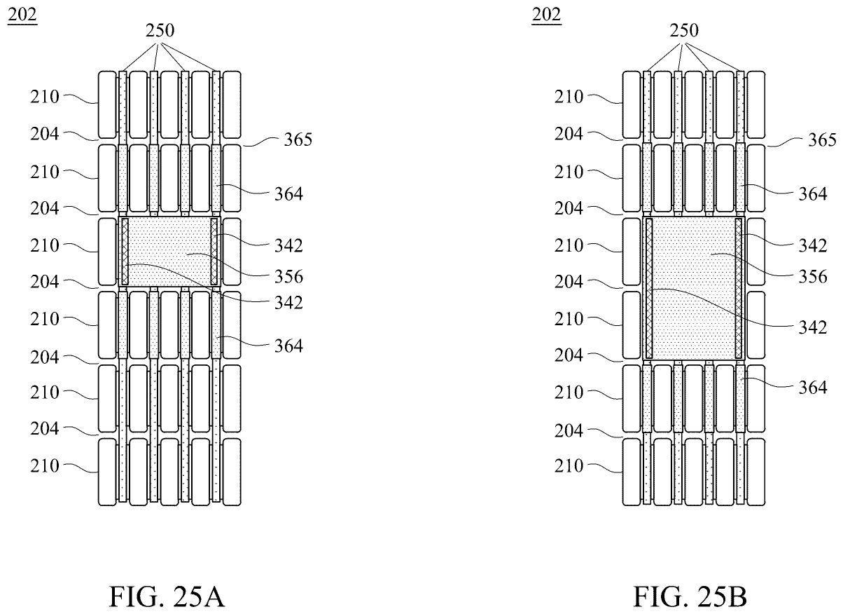

FIG. 25A and FIG. 25B are two different schematic plan views of a wafer substrate 202. These figures are similar to FIG. 24A and FIG. 24B, except that the CPODE dielectric structures 364 are not physically connected to the FTC 356. However, transistors are still disabled in area 365.

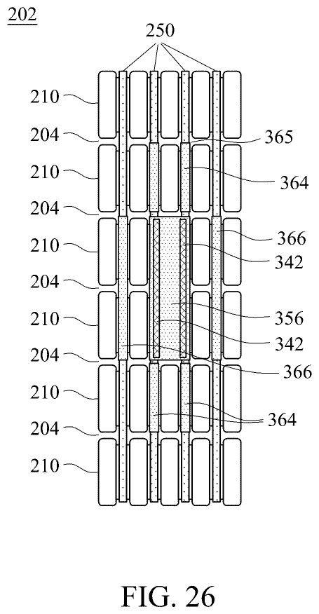

FIG. 26 is another schematic plan view of a wafer substrate 202. Whereas the CPODE dielectric structures 364 in FIGS. 24A-25B were located above or below the FTC 356, in this figure, there are also two CPODE dielectric structures 366 located to each side of the FTC 356. The transistors directly above, below, and to each side of the FTC are disabled, but the diagonal transistors are not disabled as they are in FIGS. 24A-25B.

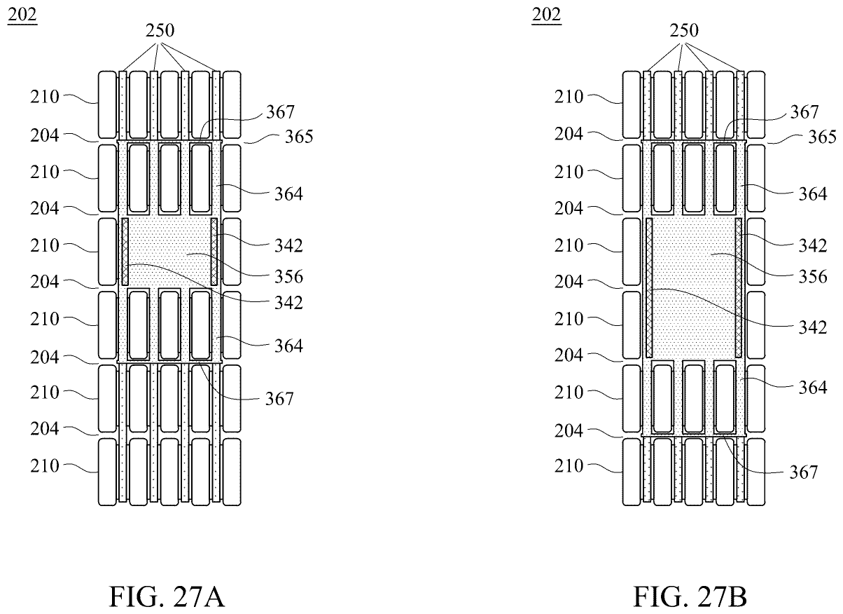

FIG. 27A and FIG. 27B are two additional different schematic plan views of a wafer substrate 202. These figures are similar to FIG. 24A and FIG. 24B, but also include CMG structures 367 at the far ends of the CPODE dielectric structures 364. Parasitic capacitance in the CPODE dielectric structures can be reduced using such CMG structures to remove high-k dielectric materials from the sidewalls of the CPODE dielectric structure.

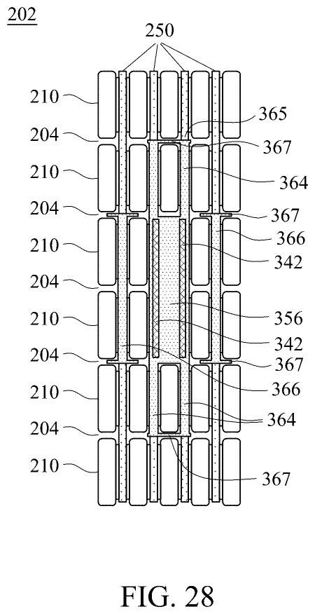

FIG. 28 is another schematic plan view of a wafer substrate 202. This figure is similar to FIG. 26, but also includes six CMG structures 367 at the far ends of the CPODE dielectric structures 364. Again, the transistors directly above, below, and to each side of the FTC are disabled, but the diagonal transistors are not disabled as they are in FIGS. 24A-25B.

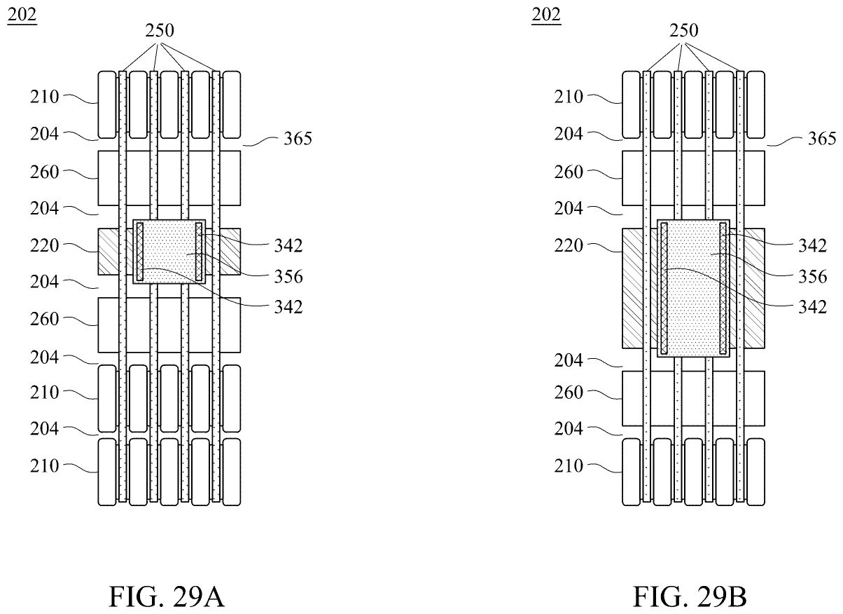

FIG. 29A and FIG. 29B are two additional different schematic plan views of a wafer substrate 202. In these figures, S/D regions 210 are not formed around the perimeter of the FTC 356. Here, the semiconducting fins 260 are visible in the rows above and below the FTC 356. This also disables transistors in the area 365 around the FTC. From a vertical perspective, it is noted that the perimeter is still filled by ILD regions 220.

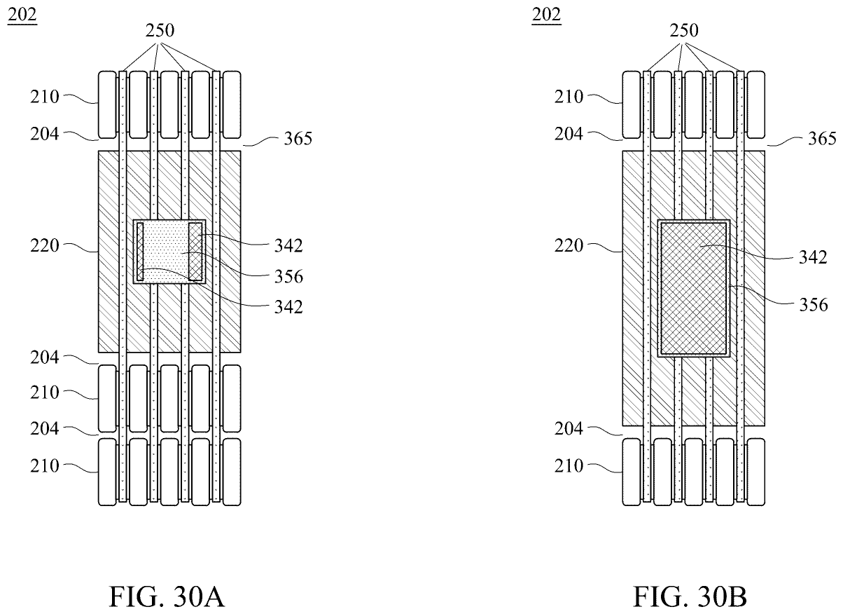

FIG. 30A and FIG. 30B are two additional different schematic plan views of a wafer substrate 202. In these figures, S/D regions 210 and semiconducting fins are not formed around the perimeter of the FTC 356. This also disables transistors in the area 365 around the FTC. Again, from a vertical perspective, it is noted that the perimeter is still filled by ILD regions 220. In FIG. 30A, the CPODE FTVs 342 are also illustrated as having different sizes or surface areas. In FIG. 30B, the CPODE FTV 342 is also illustrated as filling the FTC 356.

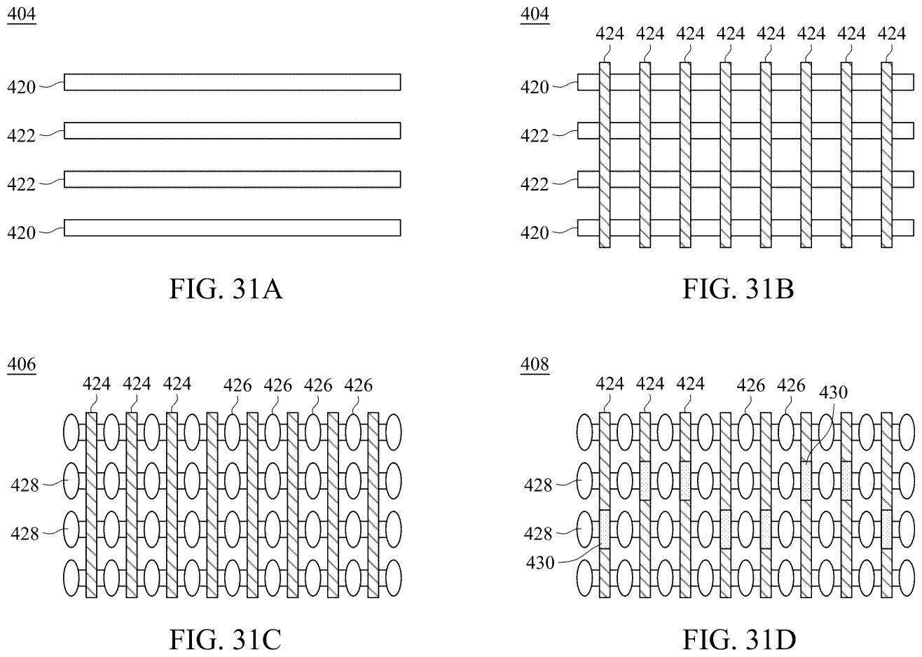

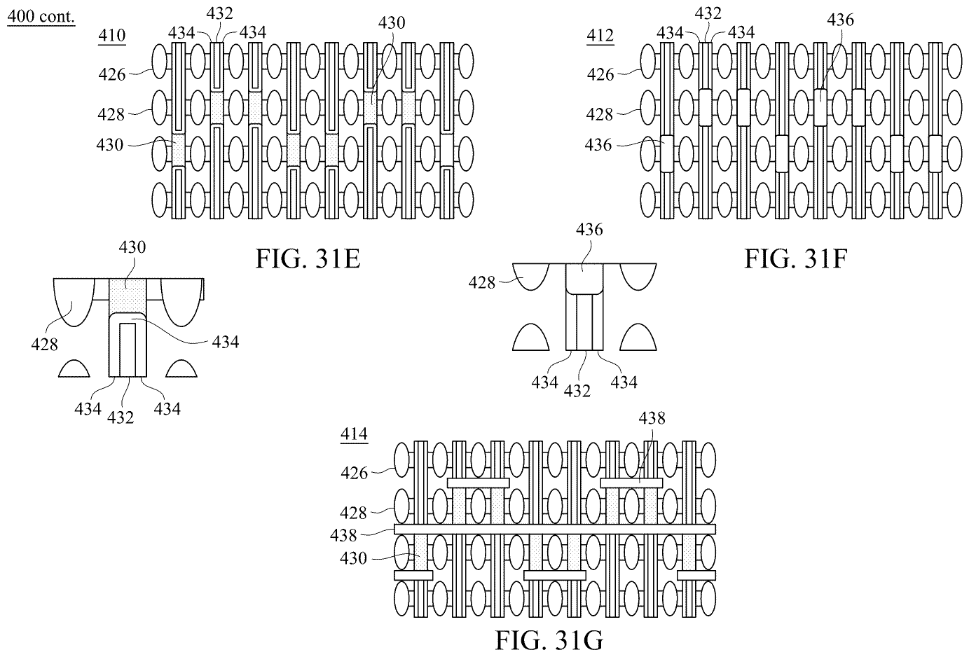

FIG. 31A-31G together illustrate a general method 400 for reducing layout-dependent effects and reducing parasitic capacitance during manufacturing of the transistors/integrated circuits of the present disclosure.

In step 402 as illustrated in FIG. 31A, semiconducting channels are formed in a substrate. Here, PMOS channels 420 and NMOS channels 422 are illustrated. In step 404 as illustrated in FIG. 31B, dummy gates 424 are formed.

In step 406 as illustrated in FIG. 31C, source/drain regions 426, 428 are formed upon the semiconducting channels 420, 422 and to either side of a dummy gate 424. This may be done, for example, by deposition and appropriate doping of epitaxial silicon.

In optional step 408 as illustrated in FIG. 31D, portions of one or more dummy gates 424 may be replaced with a dielectric structure 430 to disable the transistor that would otherwise be formed in a given location. This dielectric structure extends along the same axis as the dummy gates 424. However, using such dielectric structures 430 may increase the risk of metal gate tilting that may occur due to dummy gate bending.

In step 410 as illustrated in FIG. 31E, the dummy gates are removed and replaced with gate electrodes 432. The gate electrodes are usually a metal. In addition, the metal gates are formed with a dielectric spacer 434 on all sides. If the dielectric structure 430 is formed, the dielectric spacer 434 directly contacts the dielectric structure 430 (see the magnified view). A metal boundary effect thus occurs which can cause undesirable voltage shift.

In step 412 as illustrated in FIG. 31F, a dielectric structure 436 is formed by replacing the gate electrode, to disable the transistor that is formed in a given location. This dielectric structure extends along the same axis as the gate electrodes 432. When these dielectric structures are formed instead, the dielectric spacer 434 is only present on two sides of the gate electrode 432, and there is no dielectric spacer between the gate electrode 432 and the dielectric structure 436 (see the magnified view).

In optional step 414 as illustrated in FIG. 31G, dielectric cut metal gate (CMG) trenches 438 are formed along with dielectric structures 430. The CMG trenches are formed perpendicular to the axis of the gate electrodes 432. As an alternative, the formation of CMG trenches can reduce or eliminate the metal boundary effect that would otherwise occur. In the magnified view, there is no dielectric spacer between the gate electrode 432 and the dielectric structure 430 (see the magnified view).

It is noted that certain conventional steps are not completely described each time in the discussion below, and may be merely referred to with respect to their result. For example, a pattern/structure may be formed in a given layer by applying a photoresist layer, patterning the photoresist layer, developing the photoresist layer, and then etching, but the discussion below may refer only to patterning the given layer. For completeness, some of these various steps are described now.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

The methods and systems of the present disclosure include several different dielectric structures. Such dielectric structures can be made from any suitable combination of dielectric materials. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

The methods of the present disclosure have several advantages. First, the resulting feedthrough vias have high area efficiency. Second, they also have low parasitic capacitance. They enable efficient and effective communication of electrical signals for devices perpendicular to the metal gate electrodes, providing good communication in second axis. Third, routing can thus be simplified. Fourth, lower resistive metal contacts can also be formed, improving communication of electrical signals. Fifth, layout-dependent effects can also be reduced with appropriate disabling of adjacent transistors. Sixth, new masks are not needed for practicing the methods described herein. Other advantages are also possible in the methods and layouts described herein.

Additional processing steps may be performed to obtain semiconductor devices containing the transistors containing a jog region with a CPODE feedthrough via. The semiconductor devices might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

The present disclosure thus relates in some embodiments to methods for forming a CPODE feedthrough via (FTV) on a substrate. A portion of a semiconducting fin in a jog region on a front side of the substrate is exposed. Etching is performed to remove the exposed portion of the semiconducting fin and create a first trench in the substrate. The first trench is filled with at least one dielectric material to form a dielectric trench. The dielectric trench is then etched to an intermediate depth to form a second trench within the dielectric trench. The second trench is filled with an electrically conductive material. The dielectric trench is then etched from the back side of the substrate to form a backside volume that exposes the electrically conductive material in the second trench. The backside volume is filled with additional electrically conductive material to form the CPODE FTV.

Also disclosed in various embodiments are methods for forming a longitudinal feedthrough via (FTV) and a latitudinal FTV. A substrate having a semiconducting fin on a front side of the substrate that extends in a longitudinal direction and changes width at a jog region is received. A cut metal gate (CMG) trench is formed that extends in the longitudinal direction on one side of the jog region. A gate region that extends in a latitudinal direction in the jog region is removed to expose a portion of the semiconducting fin. Etching is performed to remove the exposed portion of the semiconducting fin and create a first trench in the substrate. The first trench is filled with at least one dielectric material to form a dielectric trench. The dielectric trench and the CMG trench are etched to an intermediate depth to form a second trench within the dielectric trench and a third trench within the CMG trench. The second trench and the third trench are filled with an electrically conductive material. The back side of the substrate is planarized to a depth that exposes the CMG trench. The dielectric trench and the CMG trench are etched from the back side of the substrate to form a backside volume that exposes the electrically conductive material in the second trench and a CMG backside volume that exposes the electrically conductive material in the third trench. The backside volume is filled with electrically conductive material to form the latitudinal FTV. The CMG backside volume is filled with electrically conductive material to form the longitudinal FTV.

Also disclosed in various embodiments are semiconductor devices that comprise a substrate. The substrate has a first semiconducting fin on a first region and a second semiconducting fin on a second region. The first semiconducting fin and the second semiconducting fin contact each other at a jog region. A feedthrough via is present within the jog region. The feedthrough via is surrounded by a dielectric structure that electrically isolates the first region from the second region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a CPODE feedthrough via (FTV) on a substrate, comprising:
exposing a portion of a semiconducting fin in a jog region on a front side of the substrate;
etching to remove the exposed portion of the semiconducting fin and create a first trench in the substrate;
filling the first trench with at least one dielectric material to form a dielectric trench;
etching the dielectric trench to an intermediate depth to form a second trench within the dielectric trench;
filling the second trench with an electrically conductive material;
etching the dielectric trench from the back side of the substrate to form a backside volume that exposes the electrically conductive material in the second trench;
filling the backside volume with the electrically conductive material to form the CPODE FTV.

2. The method of claim 1, wherein the jog region is located between two cut metal gate (CMG) trenches.

3. The method of claim 2, wherein the two CMG trenches extend to a CMG depth and the first trench has a depth that is equal to or greater than the CMG depth.

4. The method of claim 2, wherein the intermediate depth is less than the CMG depth.

5. The method of claim 2, further comprising planarizing a back side of the substrate to the CMG depth to expose the CMG trenches prior to etching the dielectric trench from the back side of the substrate.

6. The method of claim 5 further comprising:
etching each CMG trench to form a third trench within the CMG trench;
filling each third trench with the electrically conductive material;
etching each CMG trench from the back side of the substrate to form a CMG backside volume that exposes the electrically conductive material in the third trench;
filling each CMG backside volume with the electrically conductive material to form a CMG FTV.

7. The method of claim 1, wherein at least one dielectric layer above a source/drain region is also etched when the dielectric trench is etched to the intermediate depth, and further comprising:
etching to remove the source/drain region before filling the backside volume with the electrically conductive material.

8. The method of claim 1, further comprising forming at least one routing layer on the front side of the substrate.

9. The method of claim 1, further comprising forming at least one routing layer on the back side of the substrate.

10. The method of claim 1, wherein the portion of the semiconducting fin in the jog region is exposed by removing a gate region.

11. The method of claim 1, wherein the jog region is located between a first region and a second region of the substrate.

12. The method of claim 10, wherein a portion of the semiconducting fin in the first region has a greater width than a portion of the semiconducting fin in the second region.

13. The method of claim 10, wherein a portion of the semiconducting fin in the first region is offset from a portion of the semiconducting fin in the second region.

14. The method of claim 10, wherein the semiconducting fin splits into multiple portions in the first region, each portion having a smaller width than the semiconducting fin in the second region.

15. A method for forming a longitudinal feedthrough via (FTV) and a latitudinal FTV, comprising:
receiving a substrate having a semiconducting fin on a front side of the substrate that extends in a longitudinal direction and changes width at a jog region;
forming a cut metal gate (CMG) trench that extends in the longitudinal direction on one side of the jog region;
removing a gate region that extends in a latitudinal direction in the jog region to expose a portion of the semiconducting fin;
etching to remove the exposed portion of the semiconducting fin and create a first trench in the substrate;
filling the first trench with at least one dielectric material to form a dielectric trench;
etching the dielectric trench and the CMG trench to an intermediate depth to form a second trench within the dielectric trench and a third trench within the CMG trench;
filling the second trench and the third trench with an electrically conductive material;
planarizing a back side of the substrate to a depth that exposes the CMG trench;
etching the dielectric trench and the CMG trench from the back side of the substrate to form a backside volume that exposes the electrically conductive material in the second trench and a CMG backside volume that exposes the electrically conductive material in the third trench;
filling the backside volume with the electrically conductive material to form the latitudinal FTV; and
filling the CMG backside volume with the electrically conductive material to form the longitudinal FTV.

16. The method of claim 15, wherein at least one dielectric layer above a source/drain region is also etched when the dielectric trench is etched to the intermediate depth, and further comprising:
etching to remove the source/drain region before filling the backside volume with the electrically conductive material.

17. A semiconductor device, comprising:
a substrate;
a first semiconducting fin on a front side of the substrate in a first region and a second semiconducting fin on the front side of the substrate in a second region, wherein the first semiconducting fin and the second semiconducting fin contact each other at a jog region; and
a feedthrough via within the jog region surrounded by a dielectric structure that electrically isolates the first region from the second region.

18. The semiconductor device of claim 17, wherein the jog region is located between two cut metal gate (CMG) trenches.

19. The semiconductor device of claim 18, further comprising a feedthrough via in at least one of the two CMG trenches.

20. The semiconductor device of claim 17, wherein the first semiconducting fin and the second semiconducting fin are offset from each other.
